(19) United States
(12) Patent Application Publication
(10) Pub. No.: US 2025/0164536 A1
(43) Pub. Date: May 22, 2025

(54) NOISE ANALYSIS APPARATUS, NOISE ANALYSIS METHOD, AND PROGRAM

(71) Applicant: Mitsubishi Electric Corporation, Tokyo (JP)

(72) Inventor: Keita TAKAHASHI, Chiyoda-ku, Tokyo (JP)

(73) Assignee: Mitsubishi Electric Corporation, Tokyo (JP)

(21) Appl. No.: 18/863,664

(22) PCT Filed: Mar. 30, 2023
(86) PCT No.: PCT/JP2023/013152

§ 371 Date: Nov. 7, 2024

(30) Foreign Application Priority Data
May 17, 2022 (WO) PCT/JP2022/020532

(51) Int. Cl. G01R 29/26; G01R 23/16; G01R 31/26; H02M 3/10

(52) U.S. Cl. CPC G01R 29/26; G01R 23/16; G01R 31/2607; H02M 3/10

(57) ABSTRACT

A time range setting unit acquires a plurality of occurrence times at which switching of a semiconductor device occurs a plurality of times, respectively. A phase transform units generates a plurality of pieces of phase difference information for subjecting a noise spectrum in the switching of the semiconductor device to a phase transform to reflect a time difference between the plurality of occurrence times. An addition unit adds together a plurality of noise spectra that are obtained through a phase transform of the noise spectrum in the switching of the semiconductor device by the plurality of pieces of phase difference information, respectively, to calculate a result of calculating a sum spectrum generated by the switching of the semiconductor device.

### TECHNICAL FIELD

The present disclosure relates to a noise analysis apparatus, a noise analysis method, and a program.

### BACKGROUND ART

In order to predict electromagnetic noise caused due to switching of a semiconductor device of an electronic device, a power converter or the like, a technique of simulating and deriving noise at a noise observation point using an information processing device (hereinafter, referred to as a “noise analysis technique”) is known.

For example, there is known a noise analysis technique to perform a circuit simulation in which a propagation path for noise is modeled by a combination of circuit elements of a resistor, an inductor, and a capacitor. In contrast, it is known that when modeling using a combination of circuit elements is difficult, a noise analysis using a noise transfer function obtained through an electromagnetic field analysis is effective.

For example, Japanese Patent Laying-Open No. 2013-242649 (PTL 1) discloses a noise analysis technique in which a semiconductor device switched as controlled serves as a noise source, and a transient waveform (for example, a voltage waveform) including both that when the semiconductor device turns on and that when the semiconductor device turns off is subjected to Fourier-transform in advance to calculate a frequency spectrum of the noise source (hereinafter simply referred to as a “noise source spectrum”).

Further, after the calculation of the noise source spectrum, the noise analysis technique of PTL 1 can derive noise at the noise observation point with high accuracy while considering a complicated propagation characteristic of noise by performing a multiplication of the noise source spectrum by a noise transfer function from the noise source to reach the noise observation point.

### CITATION LIST

### Patent Literature

PTL 1: Japanese Patent Laying-Open No. 2013-242649

### SUMMARY OF INVENTION

### Technical Problem

It is often the case that a DC-DC converter switched as controlled in a relatively simple manner has a semiconductor device having an on period length and an off period length regarded to be fixed in a steady operation state. In that case, a noise analysis can be implemented by handling as a noise source a transient waveform for one switching period including one transient waveform formed when the semiconductor device turns on and one transient waveform formed when the semiconductor device turns off so as to correspond to the on and off period lengths of the semiconductor device in the steady operation state.

The transient waveforms time step needs to be shorter for a higher noise analysis accuracy in a higher frequency domain, and is generally set for example to about several [ns]. In contrast, the semiconductor device's on and off period lengths require several tens [μs], for example, and are relatively longer than the above time step.

For this mason, the number of time steps also increases for one switching period, that is, when a transient waveform of turning on once and a transient waveform of turning off once are used as noise source data. Further, when transient waveforms fora plurality of switching periods are used as noise source data, there is a concern that a long period of time may be required for Fourier transform due to an increased number of time steps subject to Fourier transform.

As described above, for a relatively simple DC-DC converter, a noise source spectrum obtained by subjecting a transient waveform for one switching period to Fourier transform can be used to perform a noise analysis in which a time width subject to Fourier transform is reduced.

In recent years, however, power conversion circuits are switched as controlled in an advanced manner, and the on and off period lengths may change even in a steady operation state. In particular, a PWM (Pulse Width Modulation) inverter is known to have a semiconductor device switched as controlled in principle with a change in its on and off period lengths. When such a power converter as described above is subjected to a noise analysis while a transient waveform including a transient waveform of turning on once and that of turning off once is used as a noise source, as described above, a behavior of a noise changing in phase as the on and off period lengths change can no longer be reflected in the noise source. As a result, there is a concern that the noise analysis may be reduced in accuracy.

In order to reflect the behavior of changing on and off period lengths, as described above, in a noise source, there is an option, that is, a noise analysis is performed using noise source data obtained by performing a Fourier transform of transient waveforms for a plurality of switching periods including turning on a plurality of times and turning off a plurality of times. In order to obtain such noise source data, a time width subject to the Fourier transform increases, and thus a period of time required for the Fourier transform increases. This results in a noise analysis consuming a long period of time, and this is an issue to be considered.

The present disclosure has been made in view of the above problem, and an object of the present disclosure is to provide a noise analysis technique capable of rapidly and accurately deriving a result of calculating a simulation of a noise that would be observed even when a semiconductor device has changing on and off period lengths.

### Solution to Problem

In an aspect of the present disclosure, a noise analysis apparatus is provided. The noise analysis apparatus calculates a sum spectrum of noise caused by switching that is at least one of turning on and turning off of a semiconductor device. The noise analysis apparatus comprises a first acquisition unit, a phase transform unit, and a first addition unit. The first acquisition unit acquires information indicating a plurality of occurrence times at which switching of the semiconductor device occurs a plurality of times, respectively, for a noise analysis target period including the plurality of times of switching of the semiconductor device. The phase transform unit generates a plurality of pieces of phase difference information respectively corresponding to the plurality of occurrence times acquired by the first acquisition unit for subjecting a noise spectrum in the switching of the semiconductor device to a phase transform to reflect a time difference of the plurality of times of switching. The first addition unit calculates the sum spectrum, the sum spectrum being obtained by adding together a plurality of noise spectra obtained through a phase transform of the noise spectrum in the switching of the semiconductor device by the plurality of pieces of phase difference information, respectively.

In another aspect of the present disclosure, a noise analysis method is provided. The noise analysis method calculates a sum spectrum of noise caused by switching that is at least one of turning on and turning off of a semiconductor device. The noise analysis method (1) acquires information indicating a plurality of occurrence times at which switching of the semiconductor device occurs a plurality of times, respectively, for a noise analysis target period including the plurality of times of switching of the semiconductor device, (2) generates a plurality of pieces of phase difference information respectively corresponding to the plurality of occurrence times for subjecting a noise spectrum in the switching of the semiconductor device to a phase transform to reflect a time difference of the plurality of times of switching, and (3) calculates the sum spectrum, the sum spectrum being obtained by adding together a plurality of noise spectra obtained through a phase transform of the noise spectrum in the switching of the semiconductor device by the plurality of pieces of phase difference information, respectively.

### Advantageous Effects of Invention

According to the present disclosure, a noise analysis technique capable of deriving a result of a calculation of a simulated noise by the simulation rapidly and accurately even when a semiconductor device has changing on and off period lengths, can be provided.

### BRIEF DESCRIPTION OF DRAWINGS

FIG. 1 is a conceptual diagram illustrating an example of a hardware configuration of a noise analysis apparatus according to the present embodiment.

FIG. 2 is a block diagram illustrating a configuration example of a noise analysis apparatus according to a first embodiment.

FIG. 3 is a circuit diagram illustrating an example of a noise analysis target.

FIG. 4 is a waveform diagram representing an example of a turn-on transient waveform (a voltage waveform).

FIG. 5 is a waveform diagram representing an example of a turn-off transient waveform (a voltage waveform).

FIG. 6 is a waveform diagram representing another example of the turn-off transient waveform (a current waveform).

FIG. 7 is a waveform diagram representing an example of a switching control signal indicated in FIG. 2.

FIG. 8 is a waveform diagram representing a turn-on transient waveform (a voltage waveform) approximated by a polygonal line.

FIG. 9 is a characteristic diagram representing an example of a noise source spectrum obtained by Fourier transform of the turn-on waveform in FIG. 8.

FIG. 10 is a block diagram illustrating a configuration example of a simulated noise calculation unit illustrated in FIG. 2.

FIG. 11 is a block diagram illustrating a configuration example of a sum calculation unit illustrated in FIG. 10.

FIG. 12 is a block diagram illustrating a configuration example of a simulated noise calculation unit for calculating simulated noise from a plurality of noise sources.

FIG. 13 is a block diagram illustrating a modification of the configuration of the simulated noise calculation unit illustrated in FIG. 2.

FIG. 14 is a block diagram illustrating a modification of a noise analysis function unit.

FIG. 15 is a block diagram illustrating a first configuration example of a process for correcting a time difference of a transient waveform.

FIG. 16 is a block diagram illustrating a second configuration example of the process for correcting a time difference of a transient waveform.

FIG. 17 is a first example of a connection diagram of a noise transfer function.

FIG. 18 is a second example of a connection diagram of the noise transfer function.

FIG. 19 is a third example of a connection diagram of a noise transfer function.

FIG. 20 is a fourth example of a connection diagram of the noise transfer function.

FIG. 21 is a block diagram illustrating a configuration example for integrating noise transfer functions.

FIG. 22 is a circuit diagram illustrating another example of a noise analysis target.

FIG. 23 is a circuit diagram illustrating still another example of the noise analysis target.

FIG. 24 is a spectrum diagram representing an example of a simulated noise calculation result of a noise analysis target circuit shown in FIG. 23.

FIG. 25 enlarges a partial frequency domain in FIG. 24.

FIG. 26 is a block diagram illustrating a configuration example of a noise analysis apparatus according to a second embodiment.

FIG. 27 is a block diagram illustrating a configuration example of a turn-on/turn-off separation unit in FIG. 26.

FIG. 28 is a block diagram illustrating a configuration example of a noise analysis apparatus according to a third embodiment.

FIG. 29 is a block diagram illustrating a function added to a simulated noise calculation unit 10 in a noise analysis according to the third embodiment.

FIG. 30 is a spectrum diagram showing an example of a simulated noise calculation result by the noise analysis according to the third embodiment.

FIG. 31 is a block diagram illustrating a configuration example of a noise analysis apparatus according to a fourth embodiment.

FIG. 32 is a block diagram illustrating a function added to a simulated noise calculation unit in a noise analysis according to the fourth embodiment.

FIG. 33 is a block diagram illustrating a hardware configuration example of an information processing device illustrated in FIG. 1.

FIG. 34 is a block diagram illustrating a modification in which phase transform is performed in the time domain.

FIG. 35 is a block diagram illustrating a first configuration example of a noise analysis apparatus to calculate a simulated noise with a noise observation point as a noise source.

FIG. 36 is a block diagram illustrating a first configuration example of a simulated noise calculation unit illustrated in FIG. 35.

FIG. 37 is a block diagram illustrating a configuration of a sum calculation unit illustrated in FIG. 36.

FIG. 38 is a block diagram illustrating a second configuration example of the simulated noise calculation unit illustrated in FIG. 35.

FIG. 39 is a block diagram illustrating a second configuration example of a noise analysis apparatus to calculate a simulated noise with a noise observation point as a noise source.

FIG. 40 is a block diagram illustrating a third configuration example of a noise analysis apparatus to calculate a simulated noise with a noise observation point as a noise source.

FIG. 41 is a block diagram illustrating a fourth configuration example of a noise analysis apparatus to calculate a simulated noise with a noise observation point as a noise source.

FIG. 42 is a block diagram illustrating a fifth configuration example of a noise analysis apparatus to calculate a simulated noise with a noise observation point as a noise source.

### DESCRIPTION OF EMBODIMENTS

Hereinafter, embodiments of the present disclosure will be described in detail with reference to the accompanying drawings. In the following, identical or equivalent components in the figures are identically denoted and will not be described redundantly in principle.

### First Embodiment

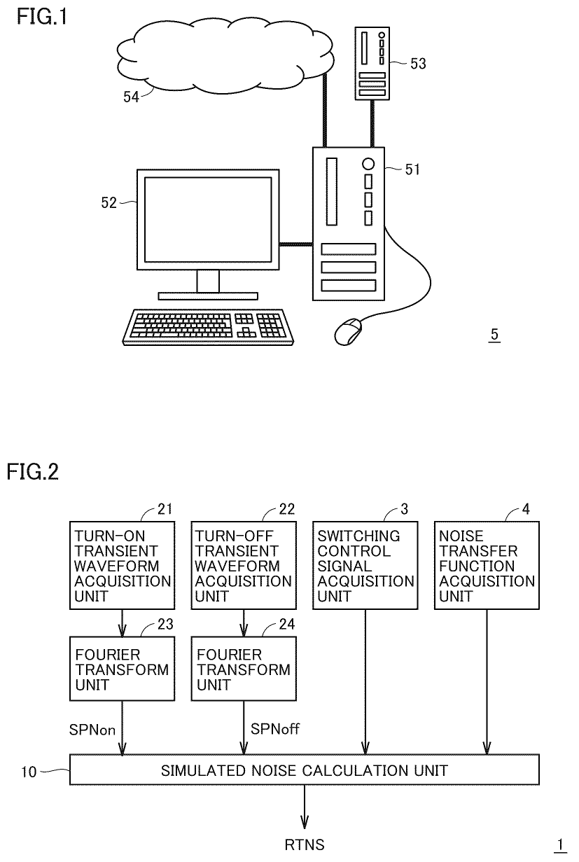

Initially, a configuration example of a noise analysis apparatus according to the present embodiment will be described with reference to FIGS. 1 and 2. FIG. 1 shows a hardware configuration example of the noise analysis apparatus, and FIG. 2 shows a block diagram illustrating a configuration example of the noise analysis apparatus according to the first embodiment.

Referring to FIG. 1, the noise analysis apparatus according to the present embodiment has a function implemented for example by an information processing device SI executing a predetermined noise analysis program. That is, when the noise analysis program is executed, each block included in noise analysis function unit 1 shown in FIG. 2 has a function implemented by information processing device 51 processing operations to configure the noise analysis apparatus according to the present embodiment or execute a noise analysis method. Thus the noise analysis technique according to the present embodiment can be applied to simulate a noise that would be observed.

That is, each block shown in the block diagrams indicated below has a function basically implemented by software processing by execution of a program. Note, however, that any block can also have at least a portion of a function thereof configured by an FPGA (a Field Programmable Gate Array), or an ASIC (an Application Specific Integrated Circuit) or a similar digital circuit, or an analog circuit.

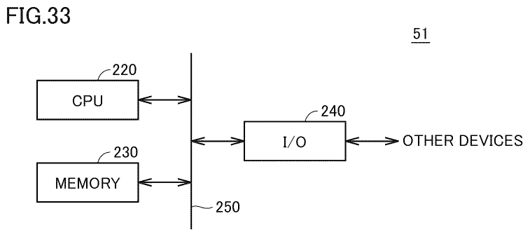

FIG. 33 shows a hardware configuration example of information processing device 51. For example, as illustrated in FIG. 33, information processing device 51 is configured based on a computer so as to include a CPU (a Central Processing Unit) 220, a memory 230, and an input/output (I/O) circuit 240. CPU 220, memory 230, and I/O circuit 240 can exchange data with one another via a bus 250.

A program including a noise analysis program is stored in advance in a partial area of memory 230, and CPU 220 can execute the program to conduct a noise analysis described later. I/O circuit 240 outputs and receives signals and data to and from other devices, for example, an information display device 52, an information processing device 53, and a cloud 54 illustrated in FIG. 1, via a communication device (not shown).

A simulated noise calculation result obtained as a result of a simulation in information processing device 51 can be displayed at information display device 52. Although information processing device 51 and information display device 52 are discrete in FIG. 1, they may be integrally configured.

The simulated noise calculation result may be stored in information processing device 51 in addition to being displayed at information display device 52. Where the simulated noise calculation result is stored is not limited to information processing device 51 that has executed the simulation, and it may be another information processing device 53 connected to information processing device 51 via a wired or wireless network, or may be cloud 54.

Referring now to FIG. 2, noise analysis function unit 1 includes a switching control signal acquisition unit 3, a noise transfer function acquisition unit 4, a turn-on transient waveform acquisition unit 21, and a turn-off transient waveform acquisition unit 22.

Turn-on transient waveform acquisition unit 21 acquires a time-based turn-on transient waveform (a voltage waveform) of a semiconductor device (or noise source) switched as controlled. Similarly, turn-off transient waveform acquisition unit 22 acquires a time-based turn-off transient waveform (a voltage waveform) of the semiconductor device.

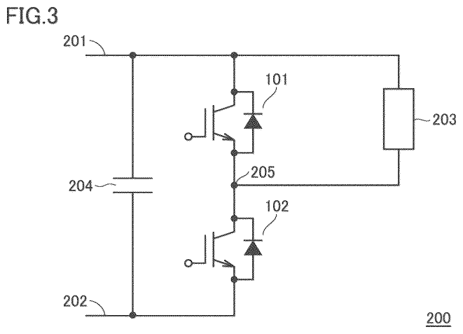

FIG. 3 shows an example of a circuit diagram of a noise analysis target. For the sake of simplicity, FIG. 3 does not show cables, power supply, and peripheral circuitry.

Referring to FIG. 3, an analysis target circuit 200 includes an upper arm semiconductor device 101 and a lower arm semiconductor device 102 connected in series between an input positive terminal 201 and an input negative terminal 202. A smoothing capacitor 204 is connected between input positive terminal 201 and input negative terminal 202.

Upper arm semiconductor device 101 has a high potential side terminal connected to input positive terminal 201, and lower arm semiconductor device 102 has a low potential side terminal connected to input negative terminal 202. Upper arm semiconductor device 101 and lower arm semiconductor device 102 have a low potential side terminal and a high potential side terminal, respectively, connected to an intermediate terminal 205. A load 203 is connected between input positive terminal 201 and intermediate terminal 205. In the configuration example in FIG. 3, upper arm semiconductor device 101 mainly operates as a diode, while lower arm semiconductor device 102 mainly operates as a transistor.

Alternatively, in the FIG. 3 configuration, load 203 can be connected between input negative terminal 202 and intermediate terminal 205. In that case, in analysis target circuit 200, upper arm semiconductor device 101 mainly operates as a transistor, and lower arm semiconductor device 102 mainly operates as a diode.

Analysis target circuit 200 can also be configured such that a plurality of sets (or arms) each of an upper arm semiconductor device and a lower arm semiconductor device connected in series are connected in parallel between input positive terminal 201 and input negative terminal 202. Each arm may not have two semiconductor devices connected in series and can have any number of semiconductor devices connected in series.

Analysis target circuit 200 has upper arm semiconductor device 101 and lower arm semiconductor device 102 each (hereinafter also collectively referred to as a “semiconductor device”) switched as controlled so that desired power conversion is performed between direct current (DC) power between input positive terminal 201 and input negative terminal 202 and power (DC power or alternate-current (AC) power) input to or output from load 203. As the semiconductor device is switched as controlled, it repeats turning on to transition from an off state to an on state and turning off to transition from the on state to the off state.

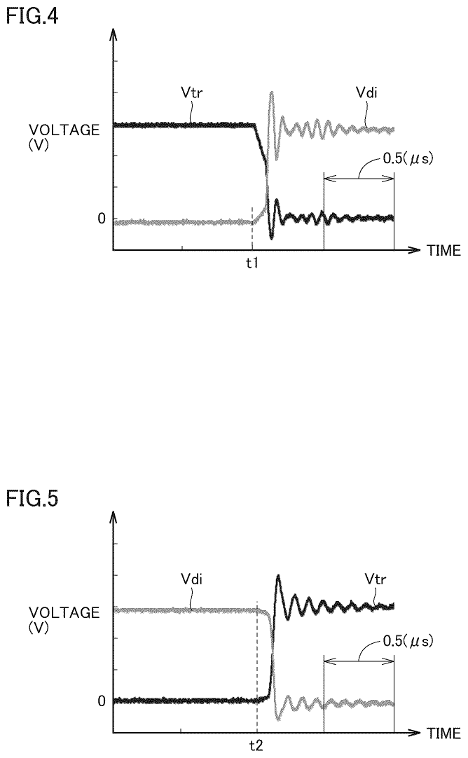

FIGS. 4 to 6 show an example of a turn-on transient waveform and a turn-off transient waveform. FIGS. 4 and 5 represent a voltage waveform as the transient waveform.

FIG. 4 represents waveforms of an inter-terminal voltage Vtr (hereinafter also referred to as a transistor voltage Vtr) of a semiconductor device (operating as a transistor) and an inter-terminal voltage Vdi (hereinafter also referred to as a diode voltage Vdi) of a semiconductor device (operating as a diode) when the semiconductor device (operating as the transistor) is turned on at t1. While the semiconductor device (operating as the transistor) is in the off period, the diode electrically conducts and accordingly, Vdi is close to zero, whereas Vtr>0 and the transistor prevents electrical conduction. When the transistor is turned on, Vtr responsively decreases to 0, whereas the diode turns off and accordingly, Vdi increases, and then a steep change in voltage is caused in Vtr and Vdi and this can be a noise source. That is, the voltage waveform after t1 et seq. corresponds to a turn-on transient waveform.

Note that t1 is a reference time for a turn-on transient waveform, and is defined as t1=0. Further, while in FIG. 4, t1 is determined to correspond to a time at which voltages Vtr and Vdi start to change, t1 serving as a reference may be determined to correspond to a time at which a gate voltage of a semiconductor device starts to change. Alternatively, t1 can also be determined to correspond to a time at which a switching control signal, which will be described later, starts to change.

Similarly. FIG. 5 represents inter-terminal voltage Vtr of the semiconductor device (operating as the transistor) and inter-terminal voltage Vdi of the semiconductor device (operating as the diode) when the semiconductor device (operating as the transistor) is turned off at t2. While the transistor is in the on period. Vtr is close to zero, whereas Vdi>0 and the diode prevents electrical conduction. When the transistor is turned off, Vtr responsively increases from 0, whereas the diode turns on and accordingly, Vdi decreases to 0, and then a steep change in voltage is caused in Vtr and Vdi and this can be a noise source. That is, the voltage waveform after t2 et seq. corresponds to a turn-off transient waveform.

Note that t2 is a reference time for a turn-off transient waveform, and is defined as t2=0. Further, while in FIG. 5, t2 is determined to correspond to a time at which voltages Vtr and Vdi start to change, t2 serving as a reference may be determined to correspond to a time at which a gate voltage of a semiconductor device starts to change in voltage. Alternatively, t2 can also be determined to correspond to a time at which a switching control signal, which will be described later, starts to change.

The changes in voltage shown in FIGS. 4 and 5 arise whenever a semiconductor device turns on and off, respectively, and the semiconductor device's turn-on and turn-off transient waveforms can be obtained in advance based on a simulation result or actual measurement data.

For example, the actual measurement data can be obtained using an oscilloscope (not shown) having a trigger function and a memory function. Specifically, a turn-on transient waveform and a turn-off transient waveform can be obtained by memorizing actually measured waveforms, as shown in FIG. 4 or FIG. 5, as triggered by the semiconductor device being turned on or off.

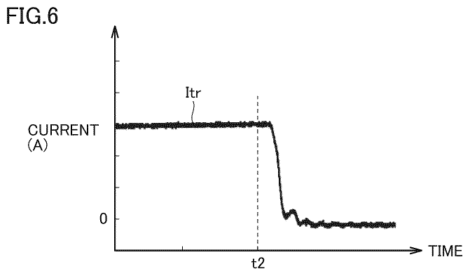

Alternatively, as shown in FIG. 6, a current waveform (for example, a transistor current Itr) may serve as a transient waveform. FIG. 6 shows, as an example, an example of an actually measured current waveform of lower arm semiconductor device 102 (mainly operating as a transistor) in analysis target circuit 200 shown in FIG. 3. A transient waveform can also be determined for a current waveform in advance based on a simulation result or actual measurement data (through an oscilloscope). Thus, turn-on transient waveform acquisition unit 21 and turn-off transient waveform acquisition unit 22 do not necessarily acquire a turn-on transient waveform and a turn-off transient waveform, respectively, in voltage waveform, and may acquire one or both of them in current waveform.

Further, a database of turn-on and turn-off transient waveforms of a semiconductor device obtained from actual measurement or through simulation can be stored in advance in any of information processing devices 51 and 53 and cloud 54. Turn-on transient waveform acquisition unit 21 and turn-off transient waveform acquisition unit 22 illustrated in FIG. 2 can access the database to acquire the turn-on and turn-off transient waveforms.

Thus, turn-on transient waveform acquisition unit 21 acquires information indicating a time-based change in voltage or current caused when turning on is done once. Similarly, turn-off transient waveform acquisition unit 22 acquires information indicating a time-based change in voltage or current caused when turning off is done once.

In a circuit in which a transistor and a diode are combined as illustrated in FIG. 3, when the transistor turns on, the diode turns off, and when the transistor turns off, the diode turns on, as illustrated in FIGS. 4 and 5. Therefore, strictly speaking, a semiconductor device's turn-on transient waveform (FIG. 4) will include Vtr's turn-on transient waveform and Vdi's turn-off transient waveform. Similarly, strictly speaking, the semiconductor device's turn-off transient waveform (FIG. 5) will include Vtr's turn-off transient waveform and Vdi's turn-on transient waveform.

Further, when noise of only one of the transistor and the diode is dominant, only one of the transistor's transient voltage waveform or transient current waveform and the diode's transient voltage waveform or transient current waveform may be applied as a turn-on transient waveform and a turn-off transient waveform.

While two semiconductor devices exist as noise sources in analysis target circuit 200 shown in FIG. 3, FIG. 2 shows a configuration for analyzing a noise output from a single noise source (a semiconductor device) for the sake of simplicity.

Referring to FIG. 2 again, switching control signal acquisition unit 3 acquires a switching control signal including information of a turn-on time and a turn-off time for the semiconductor device. The switching control signal includes time-series information of when a semiconductor device that is a noise source turns on and off.

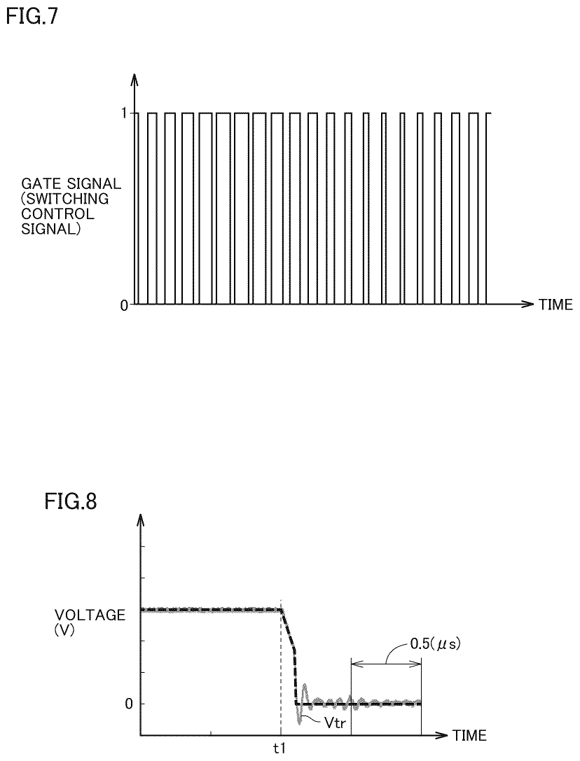

For example, a gate signal for specifying an on period and an off period for a semiconductor device, as represented in FIG. 7, can be used as the switching control signal.

Referring to FIG. 7, the gate signal is data in the time domain that is set to “1” for a period of time for which the semiconductor device should be controlled to the on state, and is set to “0” for a period of time for which the semiconductor device should be controlled to the off state. In that case, a time at which the value of the gate signal serving as the switching control signal changes from “0” to “1” corresponds to a turn-on occurrence time, and a time at which the value changes from “1” to “0” corresponds to a turn-off occurrence time.

The value of the switching control signal is not limited to digital values of “0” and “1.” and may be an analog value set to be different between the on state period and the off state period, in that case, a time at which a relationship in magnitude between the analog value and a predetermined threshold value is inverted will correspond to a turn-on time or a turn-off time.

Thus, one switching control signal is prepared for one noise source (or semiconductor device), and each switching control signal includes time-based information indicating turn-on and turn-off occurrence times for the corresponding semiconductor device (or noise source). Note that a switching control signal only for a semiconductor device (operating as a transistor) may be prepared by defining that a turn-on time for the semiconductor device (operating as the transistor) is a turn-off time for a semiconductor device (operating as a diode) and a turnoff time for the semiconductor device (operating as the transistor) is a turn-on time for the semiconductor device (operating as the diode).

Specifically, the switching control signal includes time-based information indicating a plurality of turn-on occurrence times and a plurality of turn-off occurrence times for one semiconductor device (or noise source). Further, the switching control signal may be configured by information exactly indicating these turn-on and turn-off occurrence times.

Thus, by including a plurality of turn-on occurrence times and a plurality of turn-off occurrence times, how the semiconductor device's on and off period lengths change can be reflected in data of the switching control signal.

Referring to FIG. 2 again, noise analysis function unit 1 further includes Fourier transform units 23 and 24 and a simulated noise calculation unit 10. Fourier transform unit 23 subjects a turn-on transient waveform acquired by turn-on transient waveform acquisition unit 21 to Fourier-transform to thus output a turn-on noise source spectrum SPNon in the frequency domain. Similarly, Fourier transform unit 24 subjects a turn-off transient waveform acquired by turn-off transient waveform acquisition unit 22 to Fourier-transform to thus output a turn-off noise source spectrum SPNoff in the frequency domain. Turn-on noise source spectrum SPNon and turn-off noise source spectrum SPNoff obtained by Fourier transform units 23 and 24 subjecting time-based transient waveform data to Fourier transform are input to simulated noise calculation unit 10 together with the switching control signal from switching control signal acquisition unit 3 and a noise transfer, function from noise transfer function acquisition unit 4.

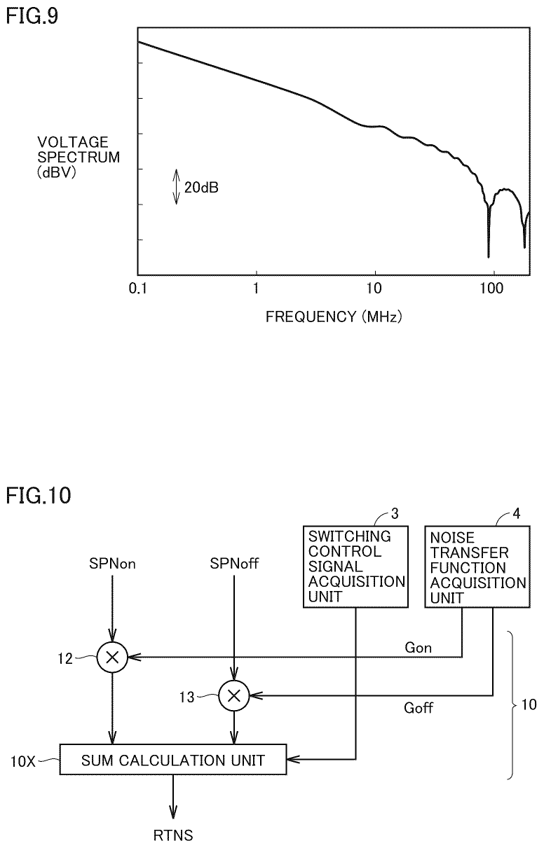

Hereinafter, an example of a process for subjecting a transient waveform to Fourier transform will be described with reference to FIGS. 8 and 9. FIG. 8 indicates an example of a polygonal approximation of a turn-on transient waveform (transistor voltage Vtr) of a semiconductor device represented in FIG. 4. When an actually measured waveform is used, it is affected by thermal noise, disturbance noise, or the like, and accordingly, it is preferable that an actually measured waveform represented in FIG. 8 by a solid line be approximated by a polygonal line as indicated by a broken line and the waveform approximated by the polygonal line be subjected to Fourier transform.

The waveform approximated by the polygonal line may be generated by automatically performing a polygonal approximation in noise analysis function unit 1, or a polygonal approximation of turn-on and turn-off transient waveforms acquired by turn-on and turn-off transient waveform acquisition units 21 and 22 may be prepared in advance. Polygonal approximation may not be used and any regression curve may be used for approximation.

FIG. 9 shows a result of a Fourier transform of the waveform approximated by the polygonal line as shown in FIG. 8, Fourier transform is typically calculated to obtain a complex spectrum. FIG. 9 plots a spectrum for each frequency in absolute value. The Fourier transform is obtained by the following expression (1), for example.

$$[ Expression 1 ]$$

$$N ( f ) = \frac{2}{T} {\int }_{- \frac{T}{2}}^{\frac{T}{2}} n ( t ) w ( t ) {e}^{- j 2 π ft} dt \qquad ( 1 )$$

In Expression (1), N(f) is a noise source spectrum at a frequency f. n(t) is a voltage value or a current value indicating a turn-on or turn-off transient waveform on a time axis with t1 and t2 defined as t=0. w(t) is a window function and T is a time width of the window function.

Alternatively, in Fourier transform units 23 and 24, a modified expression or an approximate expression that can obtain a calculation result of a Fourier transform equivalent to Expression (1) can also be used. Time width T of the window function is set as desired, and when time width T of the window function is longer than a time is length of data of a transient waveform, the data of the transient waveform may be interpolated by extrapolation. Further, while it is unnecessary to calculate f=0, i.e., a direct-current noise source spectrum, it is necessary for f=0 to divide by 2 a value obtained by Expression (1).

Fourier transform units 23 and 24 subject a transient waveform of turning on once and that of turning off once (see FIGS. 4 to 6) to Fourier transform. That is, it is understood that the number of transient waveforms (urn-ons and turn-offs) to be subjected to Fourier transform in Fourier transform units 23 and 24 is smaller than the number of a plurality of turn-on occurrence times and a plurality of turn-off occurrence times that are acquired from the switching control signal.

Referring again to FIG. 2, while in the FIG. 2 example Fourier transform units 23 and 24 subject a turn-on transient waveform and a turn-off transient waveform to Fourier transform in parallel, a common Fourier transform unit may subject a turn-on transient waveform and a turn-off transient waveform to Fourier transform sequentially.

Simulated noise calculation unit 10 calculates a simulated noise calculation result RTNS using turn-on noise source spectrum SPNon and turn-off noise source spectrum SPNoff received from Fourier transform units 23 and 24, data of the switching control signal received from switching control signal acquisition unit 3, and a noise transfer function received from noise transfer function acquisition unit 4.

FIG. 10 is a block diagram illustrating a configuration example of simulated noise calculation unit 10 shown m FIG. 2.

Referring to FIG. 10, simulated noise calculation unit 10 includes multiplication units 12 and 13, and a sum calculation unit 10X, Noise transfer function acquisition unit 4 acquires a noise transfer function Gon for a time of turning on and a noise transfer function Goff for a time of turning off. That is, in the FIG. 10 example, a noise transfer function for a time of turning on and a noise transfer function for a time of turning off are set individually.

Multiplication unit 12 multiplies turn-on noise source spectrum SPNon by noise transfer function Gon for the time of turning on. Multiplication unit 13 multiplies turn-off noise source spectrum SPNoff by noise transfer function Goff for the time of turning off.

Note that, as used herein, a noise transfer function is data including a transfer function in the frequency domain from a noise source to reach a noise observation point, and can be determined in advance for example through an electromagnetic field analysis or a circuit analysis. The noise transfer function is represented for example by a voltage or a current at the noise observation point when a voltage of 1 [V] or a current of 1 [A] is applied to the noise source. In order to consider a phase difference between the noise source and the noise observation point, the voltage or current at the noise observation point needs to be represented by a complex number.

Further, as will described hereinafter, when there are a plurality of noise sources and a plurality of noise observation points, the noise transfer function has data including noise transfer functions each for a combination of the noise sources and the noise observation points. While a target to be observed at the noise observation point is not limited to a voltage and a current and may be an electric field and a magnetic field, the present specification does not refer to an electric field or a magnetic field and refers to a voltage or a current as noise.

The data of the noise transfer function may be data of an S parameter having a port for each of a noise source and a port for a noise observation point, and by performing a calculation of converting the S parameter, what derives a voltage or a current at the noise observation point when a voltage of 1 [V] or a current of 1 [A] is applied to the noise source may be used as a noise transfer function obtained by noise transfer function acquisition unit 4.

When an S parameter having ports for a plurality of noise sources and a plurality of noise observation points is used, noise transfer functions may be derived from data of one S parameter, each for a combination of a noise source and a noise observation point. When an S parameter is converted, any impedance may be given in series with or in parallel to a noise source, and for example, a resistance of a semiconductor device when it turns on may be given in series with a voltage of 1 [V], or a capacitance of a semiconductor device when it turns off may be given in parallel to a current of 1 [A].

Alternatively, an S parameter may be replaced with a Y parameter, a Z parameter, or an F parameter that can be interconverted with the S parameter to set a noise transfer function.

As shown in FIG. 10, turn-on noise source spectrum SPNon and turn-off noise source spectrum SPNoff are multiplied by turn-on noise transfer function Gon for a time of turning on and turn-off noise transfer function Goff for a time of turning off, respectively, to calculate a simulated turn-on noise and a simulated turn-off noise. Further, the simulated turn-on noise and the simulated turn-off noise are summed together based on the data of the switching control signal to calculate a simulated noise.

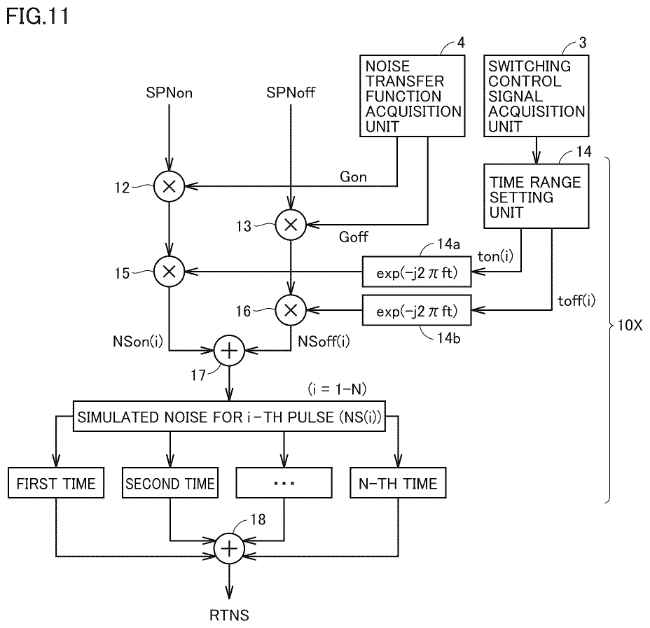

FIG. 11 is a block diagram illustrating a configuration example of sum calculation unit 10X shown in FIG. 10.

Referring to FIG. 11, sum calculation unit 10X includes a time range setting unit 14, phase transform units 14a and 14b, multiplication units 15 and 16, and addition units 17 and 18.

Time range setting unit 14 extracts, from the switching control signal received from switching control signal acquisition unit 3, turn-on occurrence times and turn-off occurrence times for first to N-th times. N being a natural number, included in a specified noise analysis target period (from a start time Tstr to an end time Tend). Thus, a turn-on time ton(i) for an i-th time and a turn-off time toff(i) for the i-th time are obtained from the switching control signal, where i=1 to N. The noise analysis target period can be set as desired, and can be a part or the entirety of a time domain corresponding to the switching control signal acquired by switching control signal acquisition unit 3.

Hereinafter, while an example in which equal numbers of turn-on and turn-off times (N turn-on times and N turn-off times) are extracted will be referred to for the sake of simplicity, there can also be a case, in reality, in which only one of a turn-on time and a turn-off time is extracted from a pulse at an end of the noise analysis target period and thus there is a difference between the number of turn-on times and the number of turn-off times.

Phase transform unit 14a calculates exp(−j·2πft) with the turn-on time for the i-th time ton(i)=t in order to provide a noise source spectrum with a difference in phase caused by a difference in turn-on time. Similarly, phase transform unit 14b calculates exp(−j·2πft) with the turn-off time for the i-th time toff(i)=t in order to express a time difference of turning off by a phase difference. The exp(−j·2πft) calculated for turn-on time ton(i) and that calculated for turn-off time toff(i) correspond to one embodiment of a “plurality of pieces of phase difference information”. By multiplying noise source spectra by the pieces of phase difference information, changes in phase respectively at turn-on times for a plurality of times and changes in phase respectively at turn-off times for the plurality of times can be included in the noise source spectra.

Multiplication unit 15 outputs a result of a multiplication of a value (or simulated turn-on noise) output from multiplication unit 12 by each of pieces of phase difference information received from phase transform unit 14a for turn-on times for a plurality of times. As a result is calculated a simulated turn-on noise NSon(i) each for a respective turn-on time ton(i) for the i-th time, where i=1 to N.

Similarly, multiplication unit 16 outputs a result of a multiplication of a value (or simulated turn-off noise) output from multiplication unit 13 by each of pieces of phase difference information received from phase transform unit 14b for turn-off times for a plurality of times. As a result is calculated a simulated turn-off noise Nsoff(i) each for a respective turn-off time toff(i) for the i-th time, where i=1 to N.

Simulated turn-on noise NSon(i) and simulated turn-off noise NSoff(i) correspond to one embodiment of a “plurality of multiplication values” that are values of a multiplication by a noise transfer function (Gon or Goff) of a plurality of noise source spectra that are a noise source spectrum (turn-on noise source spectrum SPNon or turn-off noise source spectrum SPNoff) phase-transformed respectively by pieces of phase difference information for turn-on time ton(i) and pieces of phase difference information for turn-off time toff(i). In FIGS. 10 and 11, even when multiplication units 12 and 13 and multiplication units 15 and 16 are switched positionally (or in the order of multiplication), a similar “plurality of multiplication values” can be calculated, and multiplication units 12, 13, 15 and 16 implement a function of a “first multiplication unit”.

Addition unit 17 adds simulated turn-on noise NSon(i) received from multiplication unit 15 and simulated turn-off noise NSoff(i) received from multiplication unit 16 together to calculate a simulated noise NS(i) for a pulse for the i-th time (that is, for turning on and off once). As a result, for i=1 to N, simulated noises NS(1) to NS(N) are calculated for pulses for first to N-th times.

Addition unit 18 adds simulated noises NS(1) to NS(N) that are calculated by addition unit 17 together to output simulated noise calculation result RTNS. Simulated noise calculation result RTNS is indicated as a set of data of noise intensity (for example, noise voltage [dBV]) at each frequency that is similar to the noise source spectrum indicated in FIG. 9 by way of example.

Note that the addition can also be done while weighting is changed between the pulses for the plurality of times. For example, a weighting coefficient kw(i) may be introduced to thereby multiply simulated noise NS(i) received from addition unit 17 and such multiplication values may be summed together in addition unit 18. As an example, weighting coefficient kw(i) can be set to have a large value at the center of the noise analysis target period and a small value at an end thereof.

In FIG. 11, switching control signal acquisition unit 3 corresponds to one embodiment of a “first acquisition unit,” and noise transfer function acquisition unit 4 corresponds to one embodiment of a “second acquisition unit”. Further, addition units 17 and 18 implement a function of a “first addition unit”. Further, turn-on time ton(i) and turn-off time toff(i) correspond to a “plurality of occurrence times” at which a semiconductor device switches a plurality of times.

Simulated noise calculation result RTNS indicated in FIG. 11 is calculated for one noise analysis target period set by time range setting unit 14. Therefore, when time range setting unit 14 sets a plurality of noise analysis target periods, simulated noise calculation result RTNS can be calculated for each of the plurality of noise analysis target periods. In that case, a function of performing a statistical calculation (calculating an average value, a maximum value, a minimum value, and the like) of the plurality of calculated simulated noise calculation results RTNS may further be provided, and a result obtained by the statistical calculation may be output from noise analysis function unit 1 (FIG. 2) as a final simulated noise calculation result RTNS.

Note that, the specification indicates for the sake of confirmation that in the configuration example in FIG. 11, even when the additive operations respectively by addition units 17 and 18 are switched in order, the same simulated noise calculation result RTNS can still be obtained. That is, it is also possible to adopt a configuration in which an operation by addition unit 17 to add turn-on noise and turn-off noise together is performed for a result of an additive operation performed by addition unit 18 by N times.

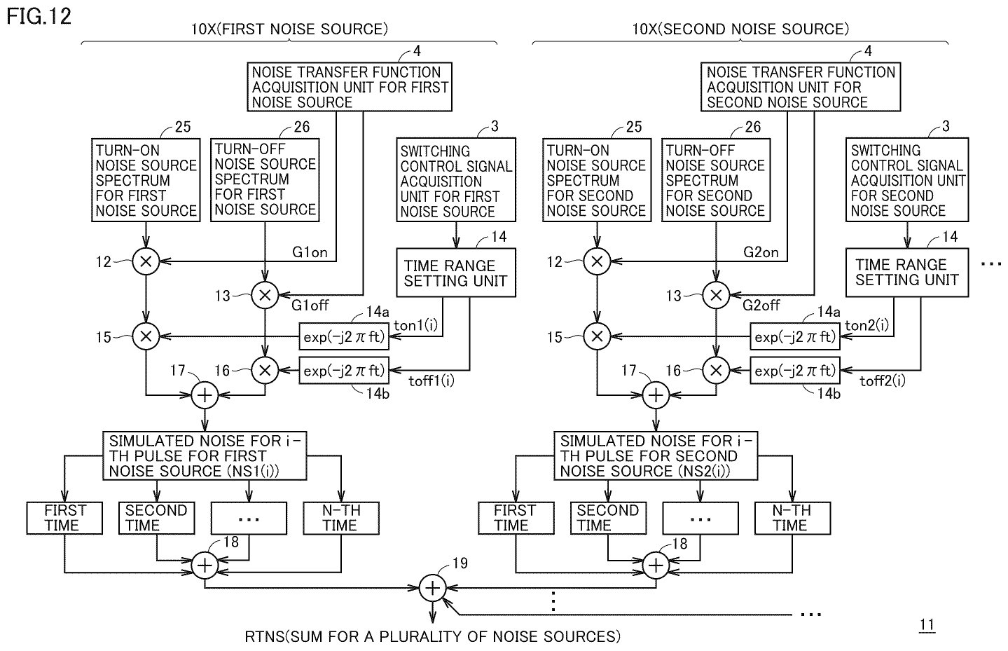

FIG. 12 shows a configuration example of a simulated noise calculation unit 11 for calculating a simulated noise from a plurality of noise sources (or semiconductor devices). For example, in analysis target circuit 200 shown in FIG. 3, the simulated noise calculation unit shown in FIG. 12 can be applied when a simulated noise is calculated with semiconductor devices 101 and 102 as discrete noise sources.

As shown in FIG. 12, simulated noise calculation unit 11 includes sum calculation unit 10X (having the same configuration as in FIG. 11) provided for each noise source, and an addition unit 19. From each sum calculation unit 10X, a simulated noise calculation result is calculated for each noise source as an output of addition unit 18.

Addition unit 19 adds together simulated noise calculation results from sum calculation units 10X each provided for a noise source, and outputs a value of a sum of simulated noises from a plurality of noise sources as simulated noise calculation result RTNS. Thus, simulated noise calculation result RTNS can be determined for any number of noise sources. That is, addition unit 19 corresponds to one embodiment of a “second addition unit”.

As described above, the noise analysis technique of the first embodiment allows a noise analysis to be performed while a time width subject to Fourier transform is minimized to a minimum number of pulses (typically, by one time) and a semiconductor device turning on/off at a plurality of pulses including information of changing on and off period lengths is a noise source. A behavior of the semiconductor device, or changing on and off period lengths, can be reflected without increasing a period of time required for directly subjecting a plurality of pulses to Fourier transform, and the noise analysis can thus be performed rapidly and accurately.

While a basic configuration for a noise analysis for one or more noise sources has been described above, a modified example and a detailed specific example of the noise analysis technique according to the first embodiment will be described below, as appropriate.

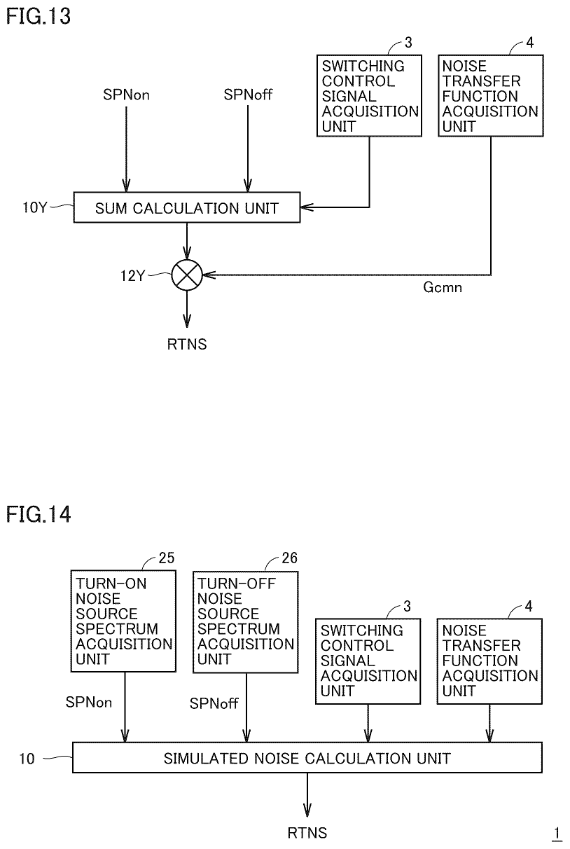

FIG. 13 shows a modification of a configuration of simulated noise calculation unit 10 (FIG. 2), as compared with FIG. 10.

Referring to FIG. 13, noise transfer function acquisition unit 4 may acquire a noise transfer function Gcmn that is set for time of turning on and time of turning off commonly. In that case, simulated noise calculation unit 10 can be configured to include a sum calculation unit 10Y and a multiplication unit 12Y.

Sum calculation unit 10Y has a configuration in which multiplication units 12 and 13 are removed from sum calculation unit 10X illustrated in FIG. 11. Further, multiplication unit 12Y is configured to multiply an output value of addition unit 18 in FIG. 11 by noise transfer function Gcmn. Thus, in FIG. 11, simulated noise calculation result RTNS with Gon=Goff=Gcmn can be obtained.

While in the FIG. 11 configuration, inputting Gon=Goff=Gcmn to multiplication units 12 and 13 can also provide the same simulated noise calculation result RTNS as described above, the FIG. 13 configuration can reduce multiplication operation once, and hence the period of time for the noise analysis.

FIG. 14 shows a modification of noise analysis function unit 1 shown in FIG. 2. In the FIG. 2 configuration, noise analysis function unit 1 is provided with Fourier transform units 23 and 24 to obtain turn-on noise source spectrum SPNon and turn-off noise source spectrum SPNoff from a turn-on transient waveform and a turn-off transient waveform.

In contrast, in the FIG. 14 modification, noise analysis function unit 1 receives turn-on noise source spectrum SPNon and turn-off noise source spectrum SPNoff obtained by subjecting a turn-on transient waveform and a turn-off transient waveform to Fourier transform in advance.

In that case, a turn-on noise source spectrum acquisition unit 25 and a turn-off noise source spectrum acquisition unit 26 acquire turn-on noise source spectrum SPNon and turn-off noise source spectrum SPNoff input to noise analysis function unit 1. In FIG. 14, turn-on noise source spectrum acquisition unit 25 and turn-off noise source spectrum acquisition unit 26 correspond to an embodiment of a “third acquisition unit”.

Turn-on noise source spectrum SPNon and turn-off noise source spectrum SPNoff thus acquired are input to simulated noise calculation unit 10, and simulated noise calculation result RTNS can be calculated by the configuration in FIG. 10 or 13.

Alternatively, FIGS. 2 and 14 can be integrated together to provide a function of automatically determining whether turn-on noise source data and turn-off noise source data input to noise analysis function unit 1 are a transient waveform (or in the time domain) or a spectrum (or in the frequency domain). In that case, a result of the automatic determination is followed to select a path via or bypassing Fourier transform units 23 and 24 of FIG. 2 to input turn-on noise source spectrum SPNon and turn-off noise source spectrum SPNoff to simulated noise calculation unit 10. Thus, both a transient waveform for the time domain) and a spectrum (or the frequency domain) are accepted as turn-on noise source data and turn-off noise source data in the noise analysis.

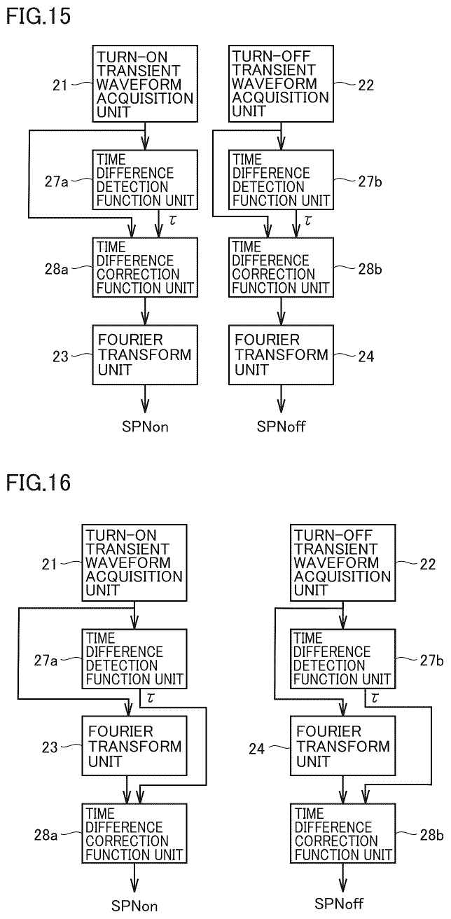

While FIGS. 4 and 5 indicate transient waveforms with t1 and t2 as the time zero serving as a reference by way of example, there may be a case in which there is a difference between t1 and t2 and the time zero at a point in time when data of a transient waveform is input. In such a case, the configuration shown in FIG. 15 can also be applied to automatically detect a turn-on occurrence time or a turn-off occurrence time from a transient waveform and automatically perform a process for correcting a time difference.

Referring to FIG. 15, a turn-on transient waveform acquired by turn-on transient waveform acquisition unit 21 (for example, see FIG. 4) is input to a time difference detection function unit 27a. Time difference detection function unit 27a stores a voltage value (or a current value) at the initial time (the time of the origin in FIG. 4) of transient waveform data as an initial value. Further, time difference detection function unit 27a at each subsequent time compares a difference between the voltage value (or current value) at the subsequent time and the initial value with a predetermined threshold value, and detects occurrence of turning on when the difference has an absolute value larger than the threshold value. The threshold value can be determined so that turning on is detected for example in a vicinity of t1 indicated in FIG. 4.

Time difference detection function unit 27a detects a time difference between the time zero (a time equivalent to the origin) and a time at which turning on is detected as a time difference τ. While it is assumed that time difference τ is set to have a positive value (τ>0) for turning on later than a reference, or the time zero, turning on earlier than the time zero can be handled with a negative value (τ<0).

A time difference correction function unit 28a corrects time-based data of a turn-on transient waveform that is acquired by turn-on transient waveform acquisition unit 21 in accordance with time difference r that is detected by time difference detection function unit 27a to obtain a corrected turn-on transient waveform, and inputs the corrected turn-on transient waveform to Fourier transform unit 23.

Similarly, a time difference detection function unit 27b and a time difference correction function unit 28b similar to time difference detection function unit 27a and time difference correction function unit 28a are also provided for a turn-off transient waveform acquired by turn-off transient waveform acquisition unit 22 (for example, see FIG. 5). That is, time difference detection function unit 27b detects a time difference between the time zero (a time equivalent to the origin) and a time at which turning off is detected as time difference τ. Note that while time difference τ (or time difference detection function unit 27a) for turning on and time difference τ (or time difference detection function unit 27b) for turning off are represented by the same symbol for the sake of simplicity, in reality, they can have different values, Time difference τ for turning off can also be set to have a positive value (τ>0) when turning off occurs later than the reference or the time zero, and can be set to have a negative value (τ<0) when turning off occurs earlier than the time zero.

With such a configuration, even when a voltage waveform or a current waveform with a turn-on time and a turn-off time that are not the time zero is received, a time difference from the turn-on time or the turn-off time can be automatically corrected to obtain transient waveform data for obtaining turn-on noise source spectrum SPNon and turn-off noise source spectrum SPNoff.

Alternatively, as shown in FIG. 16, time difference correction function units 28a and 28b may be disposed at a stage subsequent to Fourier transform units 23 and 24. In that case, time difference correction function units 28a and 28b are configured to multiply outputs of Fourier transform units 23 and 24 by exp(−j·2πf(−τ))=exp(j·2πfτ) in accordance with time difference r detected by time difference detection function units 27a and 27b. The configuration example in FIG. 16 can also provide turn-on noise source spectrum SPNon and turn-off noise source spectrum SPNoff similar to those in FIG. 15.

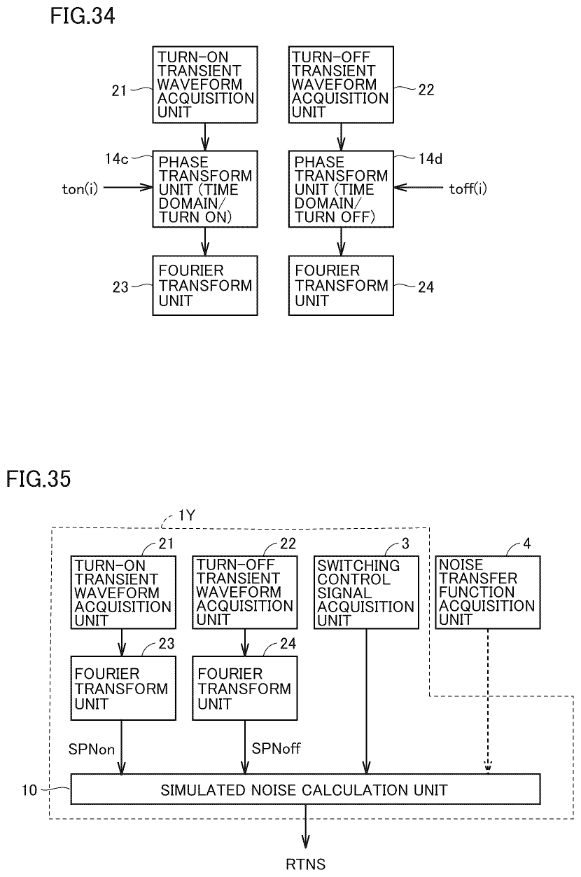

For example, while in FIG. 11, a phase transform is performed by multiplying exp(−j·2πft) calculated for each of turn-on time ton(i) and turn-off time toff(i) in the frequency domain, the configuration shown in FIG. 34 also allows a modification to perform phase transform in the time domain.

FIG. 34 is a block diagram illustrating a modification to perform phase transform in the time domain. Referring to FIG. 34, a turn-on transient waveform acquired by turn-on transient waveform acquisition unit 21 is input to a phase transform unit 14c. Phase transform unit 14c receives turn-on time ton(i) extracted by time range setting unit 14, and outputs a turn-on transient waveform shifted on the time axis in accordance with time differences each corresponding to a respective turn-on time ton(i). In this manner, a turn-on transient waveform (or waveform data) with a phase difference reflected in the time domain is input to Fourier transform unit 23. Fourier transform unit 23 subjects to Fourier-transform a turn-on transient waveform (or waveform data) for each turn-on time ton(i) that is output from phase transform unit 14c.

Similarly, a turn-off transient waveform acquired by turn-off transient waveform acquisition unit 22 is input to a phase transform unit 14d. Phase transform unit 14d receives turn-off time toff(i) extracted by time range setting unit 14, and outputs a turn-off transient waveform shifted on the time axis in accordance with time differences each corresponding to a respective turn-off time toff(i). Fourier transform unit 24 subjects to Fourier-transform a turn-off transient waveform for waveform data) for each turn-off time ton(i) that is output from phase transform unit 14d.

Sum calculation unit 10X shown in FIG. 11 can be modified to have phase transform units 14a and 14b and multiplication units 15 and 16 replaced with the configuration in FIG. 34 and have multiplication units 12 and 13 to multiply outputs of Fourier transform units 23 and 24 by noise transfer functions Gon and Goff to calculate simulated turn-off noise NSoff(i) and simulated turn-on noise NSon(i).

Even if phase transform by phase difference information is performed in the time domain by the modification shown in FIG. 34, a pulse including turning on and turning off may not be entirely subject to the Fourier transform, and some effect can be enjoyed for reducing the number of time steps subject to Fourier transform. It should be noted, however, that as performing Fourier transform after phase transform requires performing Fourier transform for the number of turning on and off done, and performing phase transform by multiplication in the frequency domain more effectively reduces a load of an operation for Fourier transform.

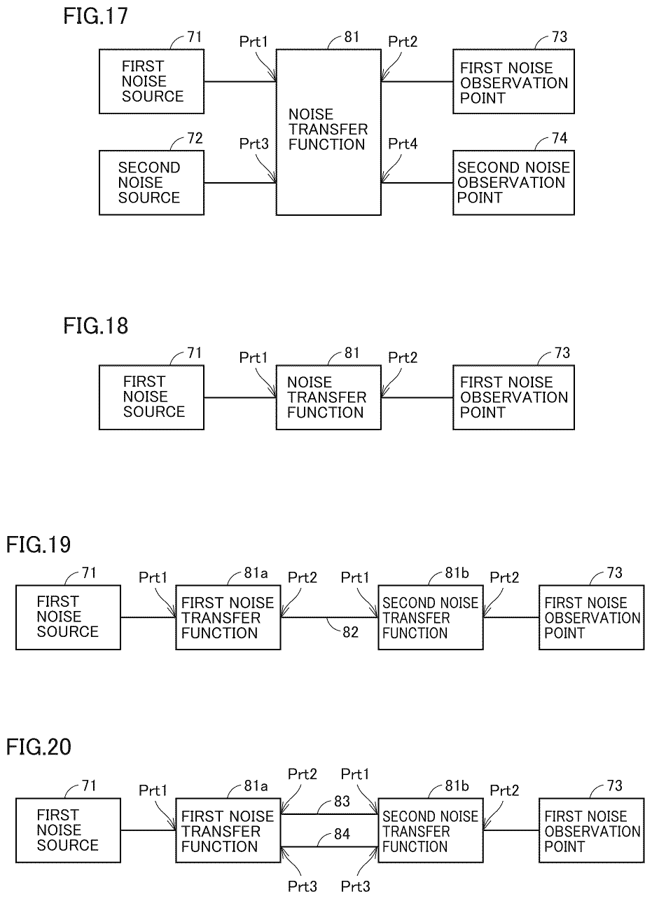

Hereinafter, exemplary connections of a noise transfer function will be described with reference to FIGS. 17 to 21 by indicating by way of example that the noise transfer function is an S parameter. As has been discussed above, a noise transfer function means a transfer function for noise in the frequency domain along a propagation path from a noise source to reach a noise observation point.

FIG. 17 shows, as a first example, a connection diagram when there are two noise sources and two noise observation points.

As shown in FIG. 17, a noise transfer function 81 has four ports Prt1 to Prt4 connected to a first noise source 71, a second noise source 72, a first noise observation point 73, and a second noise observation point 74, respectively. First noise source 71 and second noise source 72 correspond for example to upper arm semiconductor device 101 and lower arm semiconductor device 102, respectively, in analysis target circuit 200 illustrated in FIG. 3. The number of ports is not limited to four and may be any number.

FIG. 18 shows a connection diagram for a single noise source and a single noise observation point as a second example.

In FIG. 18, noise transfer function 81 has two ports Prt1 and Prt2, and port Prt1 is connected to first noise source 71 and port Prt2 is connected to first noise observation point 73.

A noise transfer function (Gon, Goff, Gcmn) used for a noise analysis can be acquired by deriving in advance a transfer function between a noise source and a noise observation point to be subjected to a noise analysis, and reading data of the transfer function by noise transfer function acquisition unit 4.

FIG. 19 shows a connection diagram when a transfer function is divided into two via a relay point as a third example.

As shown in FIG. 19, a transfer function between first noise source 71 and first noise observation point 73 is divided into a first noise transfer function 81a between first noise source 71 and a relay point 82 and a second noise transfer function 81b between first noise observation point 73 and a relay point 82. That is, in FIG. 19, a propagation path between first noise source 71 and first noise observation point 73 is divided into two propagation paths via relay point 82, and first noise transfer function 81a and second noise transfer function 81b correspond to transfer functions for the two propagation paths, respectively.

First noise transfer function 81a and second noise transfer function 81b each have two ports Prt1 and Prt2, First noise transfer function 81a has its ports Prt1 and Prt2 connected to first noise source 71 and relay point 82, respectively. Second noise transfer function 81b has its ports Prt1 and Prt2 connected to relay point 82 and first noise observation point 73, respectively.

FIG. 20 shows, as a fourth example, a connection diagram when a transfer function is divided into two via a plurality of relay points.

As shown in FIG. 20, a transfer function between first noise source 71 and first noise observation point 73 is divided into first noise transfer function 81a between first noise source 71 and relay points 83 and 84 and second noise transfer function 81b between first noise observation point 73 and relay points 82 and 83. In FIG. 20 as well, between first noise source 71 and first noise observation point 73, division is provided into two propagation paths via relay points 83 and 84, and first noise transfer function 81a and second noise transfer function 81b respectively correspond to transfer functions for the two propagation paths.

First noise transfer function 81a and second noise transfer function 81b each have three ports Prt1 to Prt3. First noise transfer function 81a has port Prt1 connected to first noise source 71, port Prt2 connected to relay point 83, and port Prt3 connected to relay point 84. Second noise transfer function 81b has port Prt1 connected to relay point 83, port Prt2 connected to first noise observation point 73, and port Prt3 connected to relay point 84.

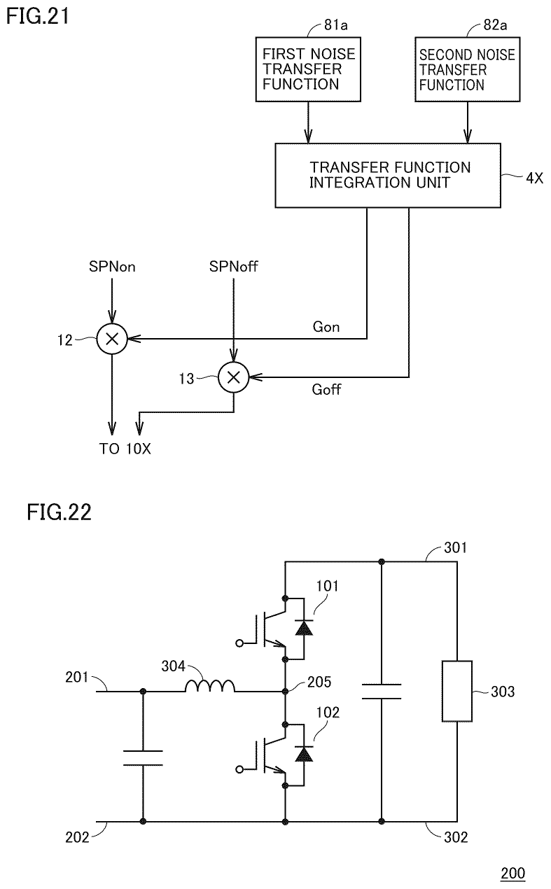

As illustrated in FIGS. 19 and 20, when a noise transfer function between a noise source and a noise observation point to be analyzed is divided into a plurality, a noise transfer function (Gon, Goff, Gcmn) used in noise analysis function unit 1 can be acquired by applying the configuration in FIG. 21.

Referring to FIG. 21, a transfer function integration unit 4X receives data of first noise transfer function 81a and that of second noise transfer function 82a in FIGS. 19 and 20 and integrates both together to provide transfer function data to output noise transfer functions Gon and Goff. Transfer function integration unit 4X disposed at a stage subsequent to noise transfer function acquisition unit 4 can integrate divided transfer functions together to obtain a noise transfer function used in noise analysis function unit 1.

FIG. 21 shows an example in which transfer function integration unit 4X is applied to the configuration in FIG. 10 in which a noise transfer function for a turn-on noise source and a noise transfer function for a turn-off noise source are individually provided. Similarly, transfer function integration unit 4X is also applicable to the configuration in FIG. 13 in which a noise transfer function is shared for a turn-on noise source and a turn-off noise source to acquire noise transfer function Gcmn.

Dividing a noise transfer function into a plurality of noise transfer functions allows the noise transfer function to be derived for each section individually. As a result, even if some section is changed in design, re-deriving only the noise transfer function for the changed section suffices, and the necessary of re-deriving the entire noise transfer function is eliminated. This can reduce a load for preparing data for the noise transfer function.

Note that a noise transfer function may not necessarily be divided into two and instead be divided into three or arty larger number. In this case as well, as well as in FIG. 20, a noise transfer function (Gon, Goff, Gcmn) used in noise analysis function unit 1 can be acquired by appropriately integrating transfer functions respectively for a plurality of divided propagation paths between a noise source and a noise observation point to be analyzed.

Note that a correspondence for connection between each port of a noise transfer function and a noise source, a noise observation point or a relay point can be defined in a connection diagram or a correspondence table in a connection setting interface that a noise analysis program comprises. Noise transfer function acquisition unit 4 can acquire a noise transfer function (Gon, Goff, Gcmn) used for a noise analysis by inputting a propagation path between a noise source and a noise observation point to be analyzed to the interface, and furthermore, disposing transfer function integration unit 4X, as necessary.

Hereinafter will further be described another example of the noise analysis target circuit and an example of a simulated noise calculation result obtained by the noise analysis apparatus according to the first embodiment.

FIG. 22 is a circuit diagram illustrating another example of a noise analysis target different than FIG. 3. In the FIG. 22 example, analysis target circuit 200 includes upper arm semiconductor device 101 and lower arm semiconductor device 102 that configure an arm similar to that in FIG. 3. Upper arm semiconductor device 101 and lower arm semiconductor device 102 are connected in series between an output positive terminal 301 and an output negative terminal 302.

Intermediate terminal 205 corresponding to a connection point of upper arm semiconductor device 101 and lower arm semiconductor device 102 is connected to input positive terminal 201 via a reactor 304. In contrast, as well as in FIG. 3, input negative terminal 202 is connected to the low potential side terminal of lower arm semiconductor device 102 and capacitor 204 is connected between input positive terminal 201 and input negative terminal 202. Output negative terminal 302 is connected to the low potential side terminal of lower arm semiconductor device 102 in common with input negative terminal 202.

A load 303 is connected between output positive terminal 301 and output negative terminal 302. In the FIG. 22 configuration, lower arm semiconductor device 102 mainly operates as a transistor, and upper arm semiconductor device 101 mainly operates as a diode. As has also been described with reference to FIG. 3, analysis target circuit 200 may include a plurality of arms each of a set of an upper arm semiconductor device and a lower arm semiconductor device connected in series, and the number of semiconductor devices connected in series is not limited to two and may be any number. Alternatively, analysis target circuit 200 may be a DC-DC converter or an AC-DC converter.

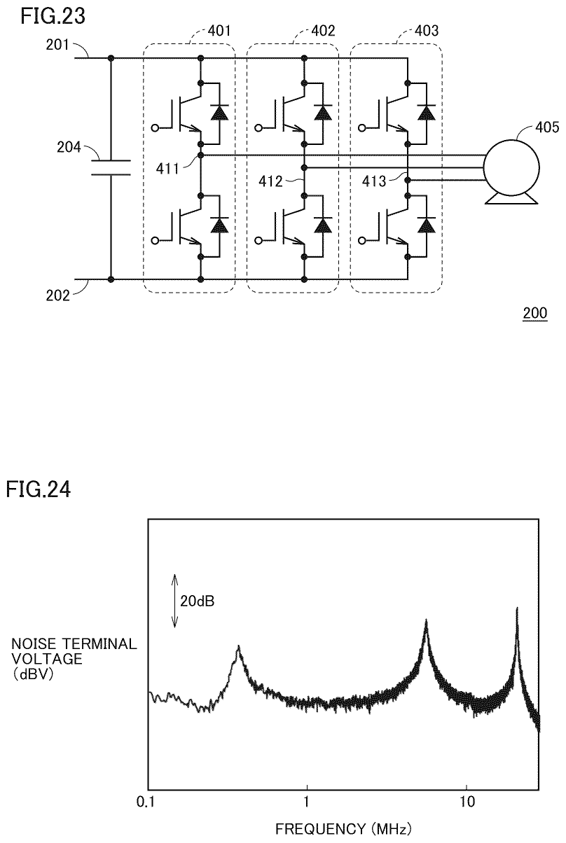

FIG. 23 shows still another example of the noise analysis target. In the FIG. 23 example, analysis target circuit 200 includes a first arm 401, a second arm 402, and a third arm 403 connected in parallel between input positive terminal 201 and input negative terminal 202. First arm 401, second arm 402, and third arm 403 are each composed of an upper atm semiconductor device and a lower arm semiconductor device connected in series between input positive terminal 201 and input negative terminal 202. First arm 401, second arm 402, and third arm 403 have intermediate terminals 411 to 413, respectively, each corresponding to a connection point of the upper arm semiconductor device and the lower arm semiconductor device, connected to an AC load 403. That is, analysis target circuit 200 in FIG. 23 operates as a three-phase inverter.

Thus, analysis target circuit 200 may be an inverter that performs DC/AC conversion, and the inverter may not have three phases and instead have any number of phases. Each arm may not have two semiconductor devices connected in series, and instead have any number of semiconductor devices connected in series.

FIG. 24 represents an example of a simulated noise calculation result for the FIG. 23 analysis target circuit (or three-phase inverter) switched as controlled. Herein, a noise analysis is conducted while it is assumed that the three-phase inverter has each phase arm composed of semiconductor devices (or a noise source) switched as controlled through PWM with an AC waveform as a modulation signal. Further, each semiconductor device controlled through PWM is switched at a frequency of 10 [kHz]. In controlling an inverter through PWM, it is known that each semiconductor device is switched as controlled by a switching control signal having changing on and off period lengths, as well as the switching control signal indicated in FIG. 7 by way of example.

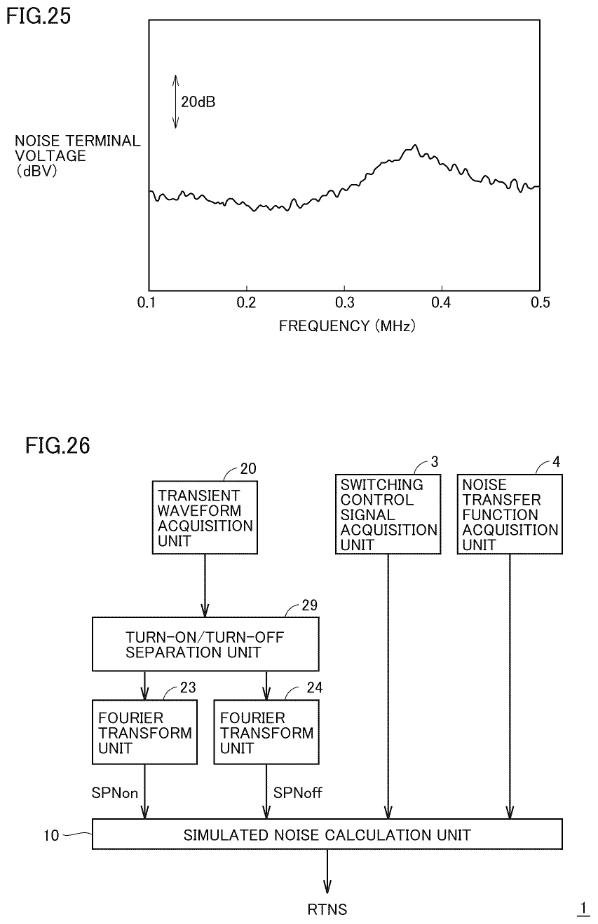

FIG. 24 plots a noise terminal voltage [dBV] indicating a noise intensity at each frequency, that is obtained as simulated noise calculation result RTNS, and FIG. 25 is an enlarged view of a range of 0.1 [MHz] to 0.5 [MHz] in FIG. 24.

For switching control with a switching frequency fixed to 10 [kHz], when a fixed on period length is provided, a noise spectrum peak occurs at an integral multiple of 10 [kHz], and spectrally, irregularities will be caused at intervals of 10 [kHz].

In contrast, the noise analysis according to the first embodiment for a three-phase inverter (see FIG. 23) controlled through PWM does not present irregularities at intervals of 10 [kHz] as described above, as shown in FIG. 25.

That is, according to the first embodiment described above, it is understood that a noise analysis for switching control accompanied by a change in on and off period lengths can be implemented without directly subjecting a plurality of pulses included in the gate signal represented in FIG. 7 to Fourier transform.

### Second Embodiment

While in the first embodiment a turn-on transient waveform and a turn-off transient waveform are distinguished and thus input to noise analysis function unit 1, in a second embodiment will be described a configuration in which a turn-on transient waveform and a turn-off transient waveform can be separated in noise analysis function unit 1.

FIG. 26 is a block diagram illustrating a configuration example of a noise analysis apparatus according to the second embodiment. Referring to FIG. 26, noise analysis function unit 1 of the noise analysis apparatus according to the second embodiment differs from the configuration of the first embodiment shown in FIG. 2 in that turn-on transient waveform acquisition unit 21 and turn-off transient waveform acquisition unit 22 are replaced with a transient waveform acquisition unit 20 and that a turn-on/turn-off separation unit 29 is further included.

Transient waveform acquisition unit 20 acquires a transient waveform including both a turn-on transient waveform and a turn-off transient waveform. That is, the second embodiment eliminates the necessity of performing a process for extracting a turn-on transient waveform and a turn-off transient waveform from a transient waveform input to noise analysis function unit 1 (or a noise analysis apparatus).

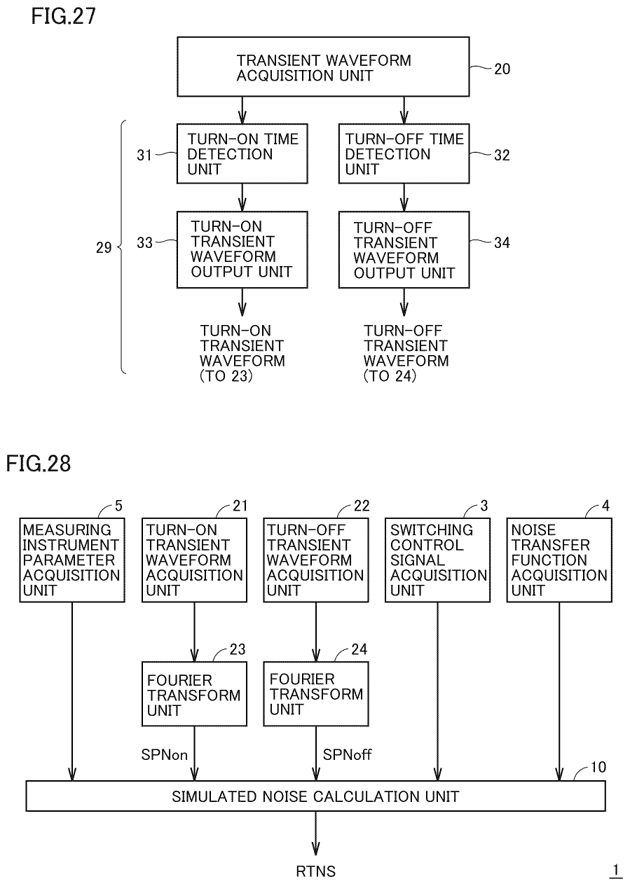

FIG. 27 shows a configuration example of turn-on/turn-off separation unit 29 shown in FIG. 26. Referring to FIG. 27, turn-on/turn-off separation unit 29 includes a turn-on time detection unit 31, a turn-off time detection unit 32, a turn-on transient waveform output unit 33, and a turn-off transient waveform output unit 34.

Turn-on time detection unit 31 detects a turn-on time of a semiconductor device for a time at which a voltage value that is included in the transient waveform obtained by transient waveform acquisition unit 20 and changes as time elapses (for example, Vtr in FIGS. 4 and 5) decreases across a predetermined threshold value. Turn-on transient waveform output unit 33 extracts a transient waveform for a certain period of time including the turn-on time detected by turn-on time detection unit 31 from the transient waveform obtained by transient waveform acquisition unit 20 to output a turn-on transient waveform.

Turn-off time detection unit 32 detects a turn-off time of the semiconductor device for a time at which the voltage value that is included in the transient waveform obtained by transient waveform acquisition unit 20 and changes as time elapses (for example, Vtr in FIGS. 4 and 5) increases across a predetermined threshold value. Turn-off transient waveform output unit 34 extracts a transient waveform for a certain period of time including the turn-off time detected by turn-off time detection unit 32 from the transient waveform obtained by transient waveform acquisition unit 20 to output a turn-off transient waveform.

Turn-on transient waveform output unit 33 and turn-off transient waveform output unit 34 output a turn-on transient waveform and a turn-off transient waveform, respectively, similar to those acquired by turn-on transient waveform acquisition unit 21 and turn-off transient waveform acquisition unit 22 shown in FIG. 2. The output turn-on and turn-off transient waveforms are input to Fourier transform units 23 and 24, respectively, in FIG. 26. Alternatively, the turn-on and turn-off transient waveforms output from turn-on and turn-off transient waveform output units 33 and 34 may be input to phase transform units 14c and 14d in FIG. 34.

When a transient waveform includes a current value (e.g., Itr in FIG. 6) which changes as time elapses, turn-on time detection unit 31 may be configured to detect a turn-on time in response to the current value increasing across a threshold value, and turn-off time detection unit 32 may be configured to detect a turn-off time in response to the current value decreasing across a threshold value.

Referring to FIG. 26 again, the remainder in configuration other than for acquiring a turn-on transient waveform and a turn-off transient waveform will not be described repeatedly in detail as it is similar to that of the first embodiment.

Thus, the noise analysis technique of the second embodiment can dispense with the step of separately preparing a turn-on transient waveform and a turn-off transient waveform for a transient waveform input to noise analysis function unit 1 (or the noise analysis apparatus).

### Third Embodiment

In general, it is known that when a noise is actually measured with a noise measuring instrument having a resolution bandwidth higher than a switching frequency of a noise source, or a semiconductor device, the measured noise appears to be larger. In a third embodiment will be described a noise analysis technique while considering a resolution bandwidth assumed at a noise observation point.

FIG. 28 is a block diagram illustrating a configuration example of a noise analysis apparatus according to the third embodiment. FIG. 28 is different from FIG. 2 in that the noise analysis apparatus according to the third embodiment comprises noise analysis function unit 1 further including a measuring instrument parameter acquisition unit 5.

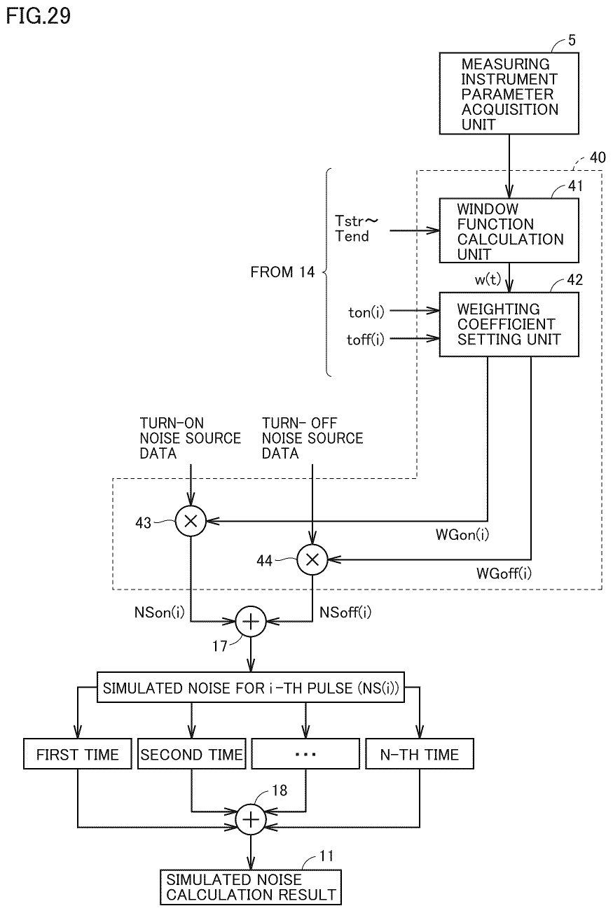

Simulated noise calculation unit 10 further includes a configuration shown in FIG. 29 in order to conduct a noise analysis reflecting information for a resolution bandwidth acquired by measuring instrument parameter acquisition unit 5 and assumed at a noise observation point. Representatively, the information includes a resolution bandwidth of a noise measuring instrument used at a noise observation point. The noise measuring instrument can be a spectrum analyzer, an EMI (Electro Magnetic Interference) receiver, or the like. The remainder in configuration and operation in FIG. 28 according to the third embodiment will not be described repeatedly in detail as it is similar to that shown in FIG. 2 (according to the first embodiment).

FIG. 29 is a block diagram illustrating a function added to simulated noise calculation unit 10 in a noise analysis according to the third embodiment.

Referring to FIG. 29, simulated noise calculation unit 10 according to the third embodiment further includes a weighting operation function unit 40. Weighting operation function unit 40 includes a window function calculation unit 41, a weighting coefficient setting unit 42, and multiplication units 43 and 44.

Window function calculation unit 41 sets a window function w(t) based on information of start time Tstr to end time Tend of a noise analysis target period as received from time range setting unit 14 (FIG. 11). Window function w(t) is set to w(t)=0 outside the noise analysis target period. Window function w(t) is set in such a shape that the window function has a value decreasing at the edges of the noise analysis target period and increasing at a center thereof.

Further, in the third embodiment, window function w(t) has a shape set to match a frequency resolution in a noise observation performed by a noise measuring instrument or the like, based on the resolution bandwidth acquired by measuring instrument parameter acquisition unit 5. For example, window function w(t) can be determined in shape so that when window function w(t) is Fourier-transformed in accordance with a predetermined overall selectivity characteristic, a DC component will be 0 [dB] and a component of a frequency of a half value of the resolution bandwidth will be −6 [dB] or −3 [dB].

Weighting coefficient setting unit 42 receives window function w(t) set by window function calculation unit 41, and turn-on time ton(i) and turn-off time toff(i) in the noise analysis target period from time range setting unit 14 (FIG. 11).

Weighting coefficient setting unit 42 outputs a value of window function w(t) for each turn-on time ton(i) as a weighting coefficient WGon(i) for that turn-on time. Similarly, weighting coefficient setting unit 42 outputs a value of window function w(t) for each turn-off time toff(i) as a weighting coefficient WGoff(i) for that turn-off time.

Multiplication unit 43 multiplies the turn-on noise source data for turn-on time ton(i) by weighting coefficient WGon(i) corresponding thereto. Similarly, multiplication unit 44 multiplies the turn-off noise source data for turn-off time toff(i) by weighting coefficient WGoff(i) corresponding thereto.

In FIG. 29, the turn-on noise source data encompasses data after information for distinguishing turn-on time ton(i) (a value output from phase transform unit 14a) is reflected with respect to turn-on noise source spectrum SPNon in simulated noise calculation unit 10. Similarly, the turn-off noise source data encompasses data after information for distinguishing turn-off time toff(i) (a value output from phase transform unit 14b) is reflected with respect to turn-off noise source spectrum SPNoff in simulated noise calculation unit 10.

In FIG. 29, measuring instrument parameter acquisition unit 5 corresponds to one embodiment of a “fourth acquisition unit”, Further, multiplication units 43 and 44 implement a function of a “second multiplication unit”.

Weighting coefficients WGon(i) and WGoff(i) may be reflected in simulated turn-on noise NSon(i) and simulated turn-off noise NSoff(i) by multiplying noise source data in the time domain thereby. For example, in the FIG. 34 configuration, weighting coefficients WGon(i) and Goff(i) for turn-on time ton(i) and turn-off time toff(i), respectively, can be input to phase transform units 14c and 14d. Then, phase transform units 14c and 14d can output results of multiplications of turn-on and turn-off transient waveforms provided with a phase difference in the time domain by weighting coefficients WGon(i) and Goff(i), respectively, to Fourier transform units 23 and 24.

Further, for weighting coefficients WGon(i) and WGoff(i) reflected in the frequency domain, even if multiplication units 43 and 44 (the second multiplication unit) are switched for the FIG. 29 example in order with multiplication units 12, 13, 15, 16 (the first multiplication units) shown in FIG. 11 etc., multiplication units 43 and 44 can similarly reflect weighting coefficients WGon(i) and WGoff(i) for multiplication values calculated by multiplication units 12, 13, 15, 16. That is, it is apparent from the description with reference to FIG. 11 etc. that these multiplication values can be multiplied by a noise transfer function in any process.

As a result, addition unit 17 can calculate for simulated noise NS(i) for the i-th pulse a value multiplied by weighting coefficients WGon(i) and WGoff(i) corresponding to a shape of window function w(t). Therefore, simulated noise calculation result RTNS that is finally calculated can also be calculated with weighting while considering where each turn-on time and each turn-off time are located in a noise analysis target period. In particular, in the third embodiment, a weighting coefficient can be set with a noise measuring instrument's resolution bandwidth reflected therein to obtain an analyzed noise calculation result with the resolution bandwidth considered.

The specification indicates for the sake of confirmation that the configuration example in FIG. 29 also provides the same simulated noise calculation result RTNS even when the additive operations respectively by addition units 17 and 18 are switched in order. That is, it is also possible to adopt a configuration in which an operation by addition unit 17 to add turn-on noise and turn-off noise together is performed for a result of an additive operation performed by addition unit 18 by N times.

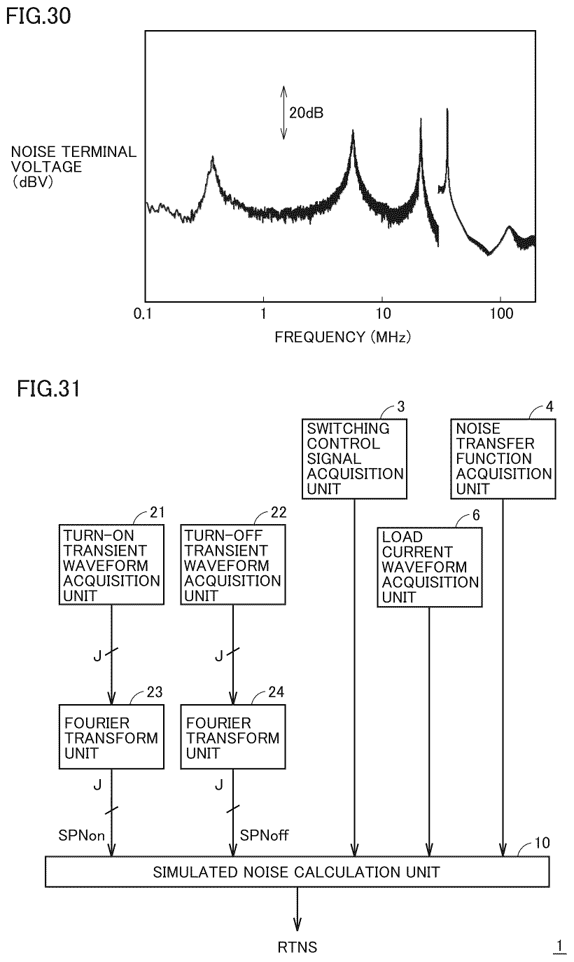

FIG. 30 is a spectrum diagram showing an example of a simulated noise calculation result by a noise analysis according to the third embodiment. FIG. 30 plots simulated noise calculation result RTNS obtained with a resolution bandwidth of 9 [kHz] for 30 [MHz] or less and a resolution bandwidth of 120 [kHz] for 30 [MHz] or more. Note that a noise source or a semiconductor device switches at a frequency similar to that in FIG. 24, i.e., 10 [kHz].

As shown in FIG. 30, in a frequency region of 30 [MHz] or more, in which the resolution bandwidth is higher than the switching frequency, a calculation result with noise appearing to be large is obtained. From this result, it is understood that a noise analysis with high accuracy while considering an effect of a resolution bandwidth of a noise measuring instrument can be performed.

In FIG. 29, a configuration in which window function w(t) is set without reflecting a parameter (or resolution bandwidth) of noise measurement can be combined with the first or second embodiment. This case also allows a noise analysis to be performed with high accuracy by performing weighting while considering where each turn-on time and each turn-off time are located in the noise analysis target period.

### Fourth Embodiment

In the first to third embodiments, an operation for simulated noise calculation result RTNS is performed while turn-on noise source spectrum SPNon at each turn-on time ton(i) is common and turn-off noise source spectrum SPNoff at each turn-off time toff(i) is common.

Meanwhile a noise source spectrum produced as a semiconductor device switches changes depending on a current being switched (or a load current). For example, when the load current decreases, a current of the semiconductor device when it switches has a reduced change, and along therewith, a time at which the semiconductor device's voltage starts to change and a gradient with which the voltage changes change. Accordingly, in the fourth embodiment, a noise analysis technique further reflecting a load current at a turn-on time and a turn-off time of a semiconductor device will be described.

FIG. 31 is a block diagram illustrating a configuration example of a noise analysis apparatus according to a fourth embodiment. Referring to FIG. 31, noise analysis function unit 1 of the noise analysis apparatus according to the fourth embodiment is different from the configuration of the first embodiment shown in FIG. 2 in that a load current waveform acquisition unit 6 is further comprised. Load current waveform acquisition unit 6 acquires a load current waveform (time based) in a time range including a noise analysis target period.

Further, in the fourth embodiment, turn-on transient waveform acquisition unit 21 and turn-off transient waveform acquisition unit 22 acquire a plurality of turn-on transient waveforms and a plurality of turn-off transient waveforms with different load currents. In FIG. 31, J turn-on transient waveforms and J turn-off transient waveforms are acquired and input to Fourier transform units 23 and 24, respectively, where J represents a natural number of 2 or more. As a result, J turn-on noise source spectra and J turn-off noise source spectra with load currents different in level are input to simulated noise calculation unit 10.

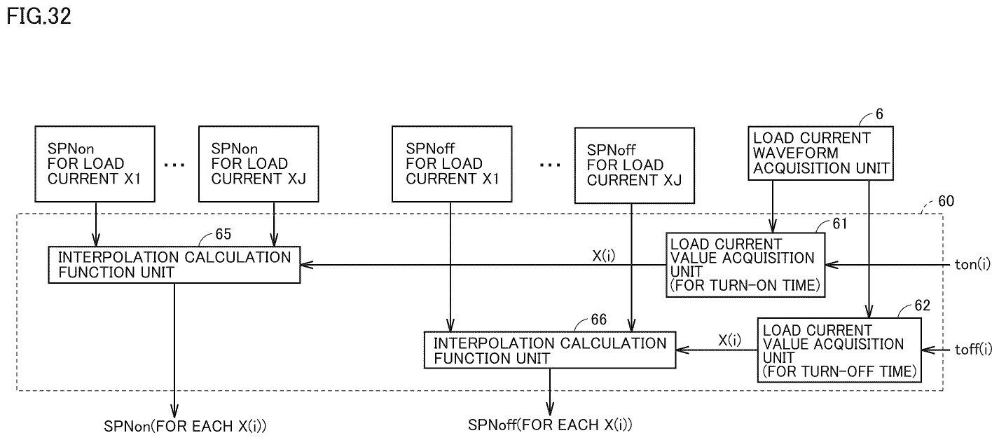

In the fourth embodiment, a function of a noise source spectrum correction unit 60 shown in FIG. 32 is added in simulated noise calculation unit 10.

Referring to FIG. 32, noise source spectrum correction unit 60 includes load current value acquisition units 61 and 62, and interpolation calculation function units 63 and 66.

Load current value acquisition unit 61 receives a load current waveform (time based) acquired by load current waveform acquisition unit 6, and turn-on time ton(i) from time range setting unit 14 (FIG. 11). Load current value acquisition unit 61 outputs a current value of the load current waveform at a respective turn-on time ton(i) as a load current value X(i) for the turn-on time. Load current value X(i) is input to interpolation calculation function unit 65.

Further, interpolation calculation function unit 65 receives turn-on noise source spectra respectively for J different load current values X1 to XJ from Fourier transform unit 23.

Based on a relationship between load current values X1 to XJ and load current value X(i) received, interpolation calculation function unit 65 outputs turn-on noise source spectrum SPNon for load current value X(i) from turn-on noise source spectra respectively for load current values X1 to XJ.

For example, turn-on noise source spectrum SPNon for load current value X(i) can be determined by linear interpolation by interpolation or extrapolation using turn-on noise source spectra for two of load current values X1 to XJ that are closest to load current value X(i).

As a result, interpolation calculation function unit 65 can calculate for each turn-on time ton(i) turn-on noise source spectrum SPNon depending on load current value X(i) at the time.

Similarly, load current value acquisition unit 62 receives a load current waveform (time based) from load current waveform acquisition unit 6, and turn-off time toff(i) from time range setting unit 14 (FIG. 11). Load current value acquisition unit 62 outputs a current value of the load current waveform at a respective turn-off time toff(i) as a load current value X(i) for the turn-off time. Load current value X(i) is input to interpolation calculation function unit 66.

Further, interpolation calculation function unit 66 receives turn-off noise source spectra respectively for J different load current values X1 to XJ from Fourier transform unit 24.

Based on a relationship between load current values X1 to XJ and load current value X(i) received, interpolation calculation function unit 66 outputs turn-off noise source spectrum SPNoff for load current value X(i) from turn-off noise source spectra respectively for load current values X1 to XJ.

For example, turn-off noise source spectrum SPNoff for load current value X(i) can be determined by linear interpolation by interpolation or extrapolation using turn-off noise source spectra for two of load current values X1 to XJ that are closest to load current value X(i).

As a result, interpolation calculation function unit 66 can calculate for each turn-off time toff(i) turn-off noise source spectrum SPNoff depending on load current value X(i) at the time. The interpolative calculation by interpolation calculation function units 65 and 66 is not limited to the above-described linear interpolation. For example, turn-on noise source spectrum SPNon and turn-off noise source spectrum SPNoff for each load current value X(i) can be determined by n-th order spline interpolation, where n is a natural number of n>2.

As described above, in the fourth embodiment, noise source spectrum correction unit 60 can calculate turn-on noise source spectrum SPNon and turn-off noise source spectrum SPNoff for each turn-on time ton(i) and each turn-off time toff(i) depending on a load current at each time.

The noise analysis technique according to the fourth embodiment employs turn-on noise source spectrum SPNon and turn-off noise source spectrum SPNoff determined by noise source spectrum correction unit 60 to perform an operation to derive simulated noise calculation result RTNS described in the first to third embodiments. In doing so, turn-on noise source spectrum SPNon and turn-off noise source spectrum SPNoff used in a calculation of a simulated noise for each of first to N-th times in FIG. 11 etc. may be different depending on a difference of load current X(i), where i=1 to N.

Thus, the noise analysis technique according to the fourth embodiment allows dependency of intensity of noise from a noise source (or a semiconductor device) on a load current to be considered, and allows a noise analysis to be further higher in accuracy.

The second to fourth embodiments can be combined with FIGS. 13, 14, 21, etc. described in the first embodiment as modifications.

(Noise Analysis Apparatus and Noise Analysis Method for Calculating Simulated Noise with Noise Observation Point as Noise Source)

In the first to fourth embodiments has been described an example of a noise analysis apparatus calculating simulated noise calculation result WINS including multiplication by a noise transfer function (Gon, Goff, Gcmn) as a sum spectrum of noise caused as a semiconductor switching device switches. However, when the problem of an increase of a time width subject to Fourier transform by performing a noise analysis through Fourier transform of a transient waveform for a plurality of switching periods including a plurality of turn-ons and a plurality of turn-offs in order to reflect a behavior of a semiconductor device, or changing on and off period lengths, in PWM waveform or the like, is considered, it is understood that the first to fourth embodiments while simulated noise calculation result RTNS without including a multiplication by a noise transfer function is calculated as the sum spectrum can also resolve the problem. A simulated noise without including a multiplication by a noise transfer function corresponds to a simulated noise with a noise observation point as a noise source. In that case, multiplying a calculated simulated noise calculation result RTNS by a noise transfer function (Gon, Goff, Gcmn) can provide simulated noise calculation result RTNS similar to that according to the first to fourth embodiments.

The noise analysis apparatuses according to the first to fourth embodiments described above can also achieve the above-described effect event when they operate to calculate a simulated noise with a noise observation point as a noise source in a manner excluding a multiplication element or a noise transfer function. Hereinafter reference will be made to FIG. 35 and FIGS. 39 to 42 to describe noise analysis function unit 1Y, which has blocks with their functions implemented by information processing device 31 processing an operation to implement a noise analysis apparatus or a noise analysis method to calculate a simulated noise with a noise observation point as a noise source.

FIG. 35 is a block diagram illustrating a first configuration example of a noise analysis apparatus that calculates a simulated noise with a noise observation point as a noise source according to the present embodiment.

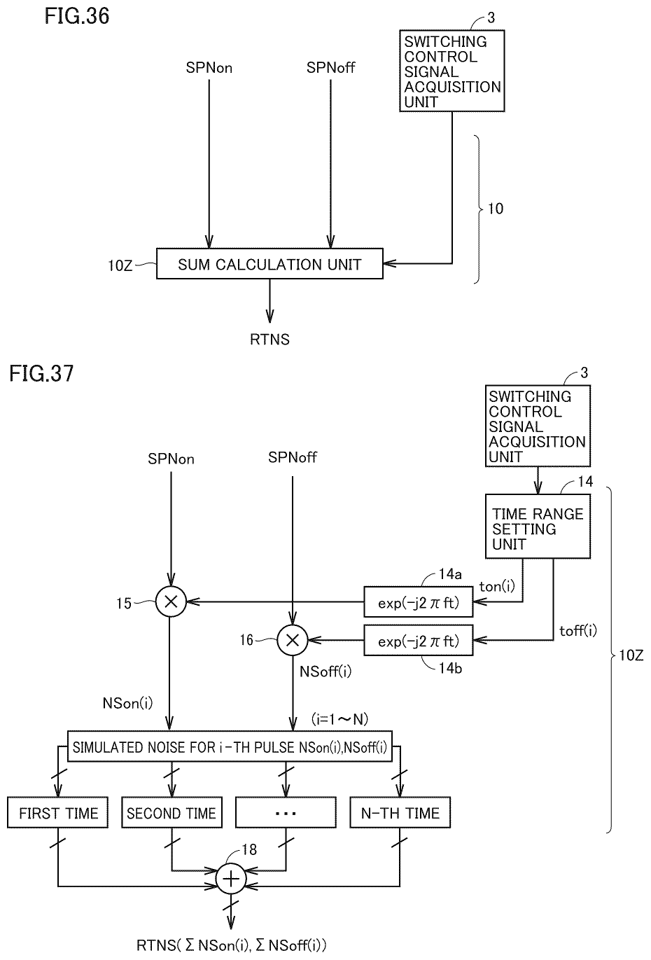

Referring to FIG. 35, noise analysis function unit 1Y according to the present embodiment, in the first configuration example, has a configuration in which noise transfer function acquisition unit 4 is removed from noise analysis function unit 1 illustrated in FIG. 2. Further, simulated noise calculation unit 10 in FIG. 35 is configured to include a sum calculation unit 10Z instead of sum calculation unit 10X in FIGS. 10 and 11, as shown in FIG. 36.

FIG. 37 shows a configuration of sum calculation unit 102 shown in FIG. 36. As shown in FIG. 37, when sum calculation unit 10Z is compared with stun calculation unit 10X shown in FIG. 11, the former is different in that multiplication units 12 and 13 for performing a multiplication by noise transfer functions Gon and Goff received from noise transfer function acquisition unit 4, and addition unit 17 are dispensed with.

As a result, in FIG. 37, simulated turn-on noise NSon(i) for the i-th time and simulated turn-off noise NSoff(i) for the i-th time are each calculated as “a plurality of noise spectra subjected to phase transform” without multiplying turn-on noise source spectrum SPNon and turn-off noise source spectrum SPNoff with phase difference information reflected therein by noise transfer functions Gon and Goff.

In FIG. 37, addition unit 18 individually calculates art addition value-NSon(i) of NSon(1) to NSon(N) from the first time to the N-th time and an addition value ΣNSoff(i) of NSoff(1) to NSoff(N) from the first time to the N-th time. As a result, sum calculation unit 10Z in FIG. 37 calculates ΣNSon(i) for a turn-on noise source spectrum and ΣNSoff(i) for a turn-off noise source spectrum us simulated noise calculation result RTNS with a noise observation point as a noise source. In that case, ΣNSon(i) and ΣNSoff(i) correspond to a sum spectrum obtained by summing together a plurality of noise spectra subjected to phase transform. In contrast, in the first to fourth embodiments, it is understood that a sum spectrum that is a sum of a plurality of noise spectra multiplied by a noise transfer function and also subjected to phase transform is calculated as simulated noise calculation result RTNS. As indicated in FIG. 37 by arrows with an oblique line. NSon(1) to NSon(N) for turning on and NSoff(1) to NSoff(N) for turning off are handled separately at an input of addition unit 18, and as a result, addition unit 18 outputs ΣNSon(i) and ΣNSoff(i) individually.

Further, sum calculation unit 1Z in FIG. 37 may be modified to perform phase transform in the time domain with the FIG. 14 configuration applied thereto. Specifically, the configuration in FIG. 37 can have phase transform units 14a and 14b and multiplication units 15 and 16 removed and simulated turn-on noise NSon(i) by N times Fourier-transformed by Fourier transform unit 23 in FIG. 34 and simulated turn-off noise NSoff(i) by N times Fourier-transformed by Fourier transform unit 24 in FIG. 34 can be input to addition unit 18 to calculate ΣNSon(i) and ΣNSoff(i) as simulated noise calculation result RTNS with a noise observation point as a noise source.

Similarly, the configuration in FIG. 13 using noise transfer function Gcmn set for time of turning on and time of turn-off commonly can also be operated as a noise analysis apparatus to calculate a simulated noise with a noise observation point as a noise source by excluding a multiplication by a noise transfer function, as shown in FIG. 3.

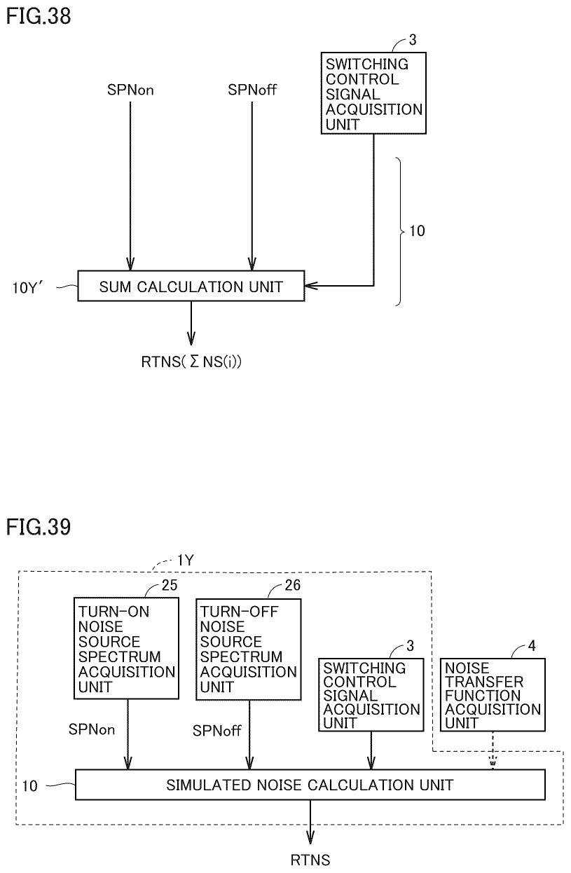

With reference to FIG. 38, simulated noise calculation unit 10 in FIG. 35 can be configured to remove multiplication unit 12Y from the configuration in FIG. 13, and further include a sum calculation unit 10Y′ instead of sum calculation unit 10Y.

Sum calculation unit 10Y′ can be configured by sum calculation unit 10Z in FIG. 37 with addition unit 18 performing an operation to add NSon(1) to NSon(N) from the first time to the N-th time together and an operation to add NSon(1) to NSoff(N) from the first time to the N-th time together, and furthermore, addition unit 17 similar to FIG. 11 provided to perform an operation to add turn-on noise and turn-off noise together. Thus, ΣNS(i) corresponding to a sum of ΣNSon(i) and ΣNSoff(i) in FIG. 37 can be output as simulated noise calculation result RTNS with a noise observation point as a noise source. In that case, ΣNS(i) corresponds to a sum spectrum obtained by summing together a plurality of noise spectra subjected to phase transform.

In doing so as well, even if the additive operations by addition units 17 and 18 are switched in order, the same simulated noise calculation result RTNS can still be calculated. That is, even when addition unit 17 performs an operation to add turn-on noise and turn-off noise together to calculate “NSon(i)+NSoff(i)” by N times and subsequently addition unit 18 determines a total sun of “NSon(1)+NSoff(1)” to “NSon(N)+NSoff(N)” the same ΣNS(i) as described above can still be calculated as simulated noise calculation result RTNS.

FIG. 38 can also be modified to perform phase transform in the time domain with the FIG. 34 configuration applied thereto. Specifically, when phase transform units 14a and 14b and multiplication units 15 and 16 are removed and in the FIG. 38 configuration sum calculation unit 10Y′ receives simulated turn-on noise NSon(i) by N times Fourier-transformed by Fourier transform unit 23 in FIG. 34 and simulated turn-off noise NSoff(i) by N times Fourier-transformed by Fourier transform unit 24 in FIG. 34, a similar ΣNS(i) can be calculated as simulated noise calculation result RTNS with a noise observation point as a noise source.

As described above, according to the present embodiment, noise analysis function unit 1Y can provide simulated noise calculation result RTNS (that is, a sum spectrum without including a multiplication by a noise transfer function) similar to simulated noise calculation result RTNS according to the first to fourth embodiments by a multiplication by a noise transfer function (Gon, Goff, Gcmn) outside the noise analysis apparatus, for example. That is, a noise analysis apparatus similar to that of the first to fourth embodiments can be configured by a noise analysis apparatus that calculates a simulated noise with a noise observation point as a noise source, as described with reference to FIGS. 35 to 42, and noise transfer function acquisition unit 4 and a multiplication element (multiplication units 12, 13 and 12Y) according to the first to fourth embodiments.

Thus, even when the noise analysis apparatus according to the present embodiment is configured to calculate a simulated noise with a noise observation point as a noise source, the noise analysis apparatus can output as simulated noise calculation result RTNS a sum spectrum reflecting a behavior of a phase changing as on and off period lengths change. In doing so, an increase of a period of time required for Fourier transform due to an increase of a time width subject to Fourier transform can be reduced to implement a rapid noise analysis.

FIG. 39 illustrates a second configuration example of a noise analysis apparatus for calculating a simulated noise with a noise observation point as a noise source, with noise analysis function unit 1Y configured to remove noise transfer function acquisition unit 4 from noise analysis function unit 1 illustrated FIG. 14, As a result, simulated noise calculation unit 10 can calculate as simulated noise calculation result RTNS a total value (or a sum spectrum) of a plurality of noise spectra subjected to phase-transform without including a multiplication by a noise transfer function (Gon, Goff, Gcmn).

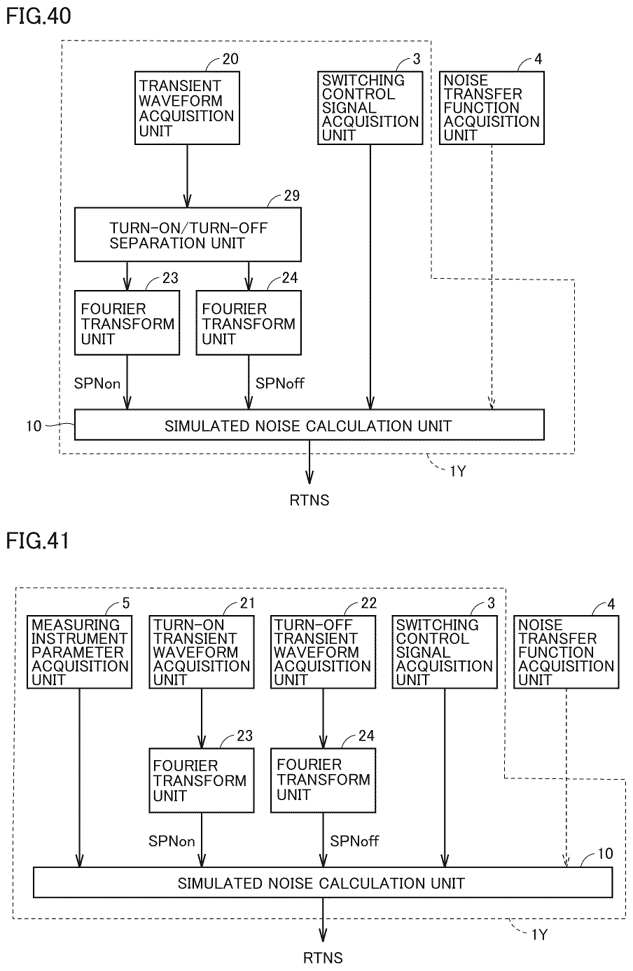

Similarly, as shown in FIGS. 40 to 42, a noise analysis apparatus calculating a simulated noise with a noise observation point as a noise source can also be configured based on the configuration of the noise analysis apparatus according to the second to fourth embodiments.

A noise analysis apparatus calculating a simulated noise with a noise observation point as a noise source (FIG. 40) in a third configuration example has noise analysis function unit 1Y configured to remove noise transfer function acquisition unit 4 from analysis function unit 1 shown in FIG. 26 (according to the second embodiment). Simulated noise calculation result RTNS corresponding to a sum spectrum obtained by summing together a plurality of noise spectra subjected to phase transform without including a multiplication by a noise transfer function (Gon, Goff, Gcmn), can thus be calculated.

Further, a noise analysis apparatus calculating a simulated noise with a noise observation point as a noise source in a fourth configuration example (FIG. 41) has noise analysis function unit 1Y configured to remove noise transfer function acquisition unit 4 from noise analysis function unit 1 shown in FIG. 28 (according to the third embodiment). As a result, as well as in FIGS. 35, 39, and 40, simulated noise calculation result RTNS corresponding to a sum spectrum obtained by summing together a plurality of noise spectra subjected to phase transform without including a multiplication by a noise transfer function (Gon, Goff, Gcmn), can be calculated.

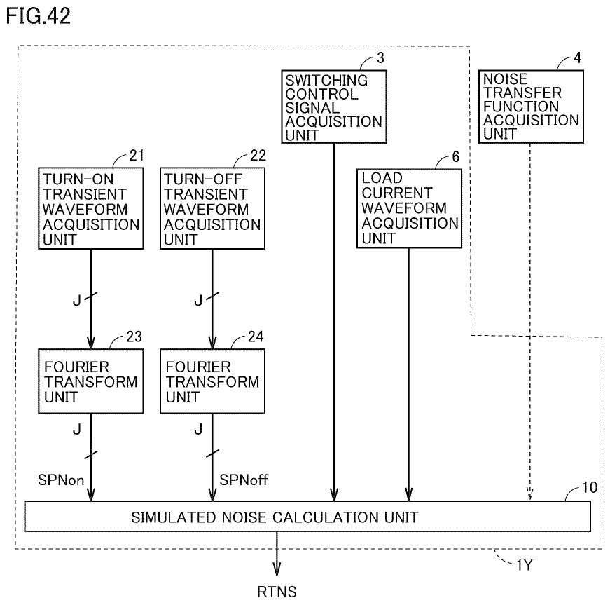

Similarly, a noise analysis apparatus calculating a simulated noise with a noise observation point as a noise source in a fifth configuration example (FIG. 42) has noise analysis function unit 1Y configured to remove noise transfer function acquisition unit 4 from noise analysis function unit 1 shown in FIG. 31 (according to the fourth embodiment). As a result, as well as in FIGS. 35 and 39 to 41, simulated noise calculation result RTNS corresponding to a sum spectrum obtained by summing together a plurality of noise spectra subjected to phase transform without including a multiplication by a noise transfer function (Gon, Goff, Gcmn), can be calculated. In each of FIGS. 39 to 42, simulated noise calculation unit 10 can be configured in a manner similar to that described with reference to FIGS. 36 to 38.

Thus, the first to fourth embodiments described above each also disclose a noise analysis apparatus that calculates a simulated noise with a noise observation point as a noise source, as has been described with reference to FIGS. 35 to 42. Even when a noise observation point is set as a noise source, the noise analysis apparatus can suppress an increase of a period of time required for the Fourier transform due to an increase of a time width subject to Fourier transform, and can output as simulated noise calculation result RTNS a sum noise spectrum reflecting a behavior of a phase changing as on and off period lengths change. This can provide a noise analysis technique that can prevent a noise analysis from consuming a long period of time and thus quickly, and accurately derive a final simulated noise calculation result.

The specification indicates for the sake of confirmation that with respect to the plurality of embodiments described above, including any combination that is not mentioned in the specification, a configuration described in each embodiment is intended from the beginning of the application to be combined with another, as appropriate, within a range without inconsistency or contradiction.

Further in the above-described embodiments has been described a configuration example of analyzing noise from both a turn-on noise source and a turn-off noise source, that is, a noise analysis technique of calculating a simulated noise for noise caused by “switching” of a semiconductor device including both turning on and turning off. That is, in the present embodiment, an example has been described in which a noise analysis according to the present disclosure is performed with both turn-on time ton(i) and turn-off time toff(i) as “a plurality of occurrence times”.

In contrast, a case in which one of a noise caused as a semiconductor device turns on and a noise caused as the semiconductor device turns off is dominantly observed, is also assumed. In such a case, it is also possible to perform a noise analysis without considering the noise source that is not dominant.

For example, when the noise at the time of turning on is dominant, simulated noise calculation result RTNS can be calculated without considering the turn-off noise source, that is, by deleting the term of NSoff. In that case, a configuration for acquiring a turn-off transient waveform or a turn-off noise source spectrum may be removed from noise analysis function unit 1. As described above, a noise analysis technique (a noise analysis technique and a noise analysis method) according to the present embodiment is applicable to calculating a simulated noise for noise caused by “switching” of a semiconductor device that is at least one of turning on and turning off In that case, a noise analysis according to the present disclosure is conducted with only one of turn-on time ton(i) and turn-off time toff(i) as “a plurality of occurrence times”.

While FIG. 1 illustrates a configuration example to implement a noise analysis apparatus by information processing device 51 executing a program (a noise analysis program) for performing a noise analysis technique according to the present embodiment, the noise analysis program may be executed by information processing device 53 or cloud 54 shown in FIG. 1. Alternatively, the execution of the noise analysis program that operates as the noise analysis apparatus may be shared by a plurality of devices. That is, the noise analysis apparatus may be configured by some or all of information processing devices 51 and 53 and cloud 54 sharing the execution of the noise analysis program.

Further, the data of the turn-on and turn-off transient waveforms (in the time domain or the frequency domain), the data of the switching control signal, and the data of the noise transfer function may be stored in any of information processing devices 51 and 53 and cloud 54. Similarly, simulated noise calculation result RTNS may not be stored in information processing device 51 exclusively, and may be stored in information processing device 53 and/or cloud 54.

Similarly, simulated noise calculation result RTNS may not be displayed by information display device 52 exclusively, and may be displayed by any of an information display device of information processing device 53 and a virtual information displaying environment of cloud 54. Contents of the virtual information displaying environment can be displayed on information display device 52 for example by information processing device 51 accessing cloud 54.

As described above, sharing a process for a noise analysis technique according to the present embodiment by a plurality of performer entities allows a noise analysis to be easily performed even if information processing device 51 exhibits low data storing or processing performance. In particular, by utilizing cloud 54, a noise analysis technique (a noise analysis program) that derives noise rapidly and accurately even when a semiconductor device has changing on and off period lengths can be easily provided to many uses as a noise analysis service via a network.

It should be understood that the embodiments disclosed herein have been described for the purpose of illustration only and in a non-restrictive manner in any respect. The scope of the present disclosure is defined by the terms of the claims, rather than the description above, and is intended to include any modifications within the meaning and scope equivalent to the terms of the claims.

### REFERENCE SIGNS LIST

1, 1Y noise analysis function unit, 3 switching control signal acquisition unit, 4 noise transfer function acquisition unit, 4X transfer function integration unit, 5 measuring instrument parameter acquisition unit, 6 load current waveform acquisition unit, 10, 11 simulated noise calculation unit, 10X, 10Y, 10Y′, 10Z sum calculation unit, 12, 12Y, 13, 15, 16, 43, 44 multiplication unit, 14 time range setting unit, 14a-14d phase transform unit, 17, 18, 19 addition unit, 20 transient waveform acquisition unit, 21 turn-on transient waveform acquisition unit, 22 turn-off transient waveform acquisition unit, 23, 24 Fourier transform unit, 25 turn-on noise source spectrum acquisition unit, 26 turn-off noise source spectrum acquisition unit, 27a, 27b time difference detection function unit, 28a, 28b time difference correction function unit, 29 turn-on/turn-off separation unit, 31 turn-on time detection unit, 32 turn-off time detection unit, 33 turn-on transient waveform output unit, 34 turn-off transient, waveform output unit, 40 weighting operation function unit, 41 window function calculation unit, 42 weighting coefficient setting unit, 51, 53 information processing device, 52 information display device, 54 cloud, 60 noise source spectrum correction unit, 61, 62 load current value acquisition unit, 65, 66 interpolation calculation function unit, 71 first noise source, 72 second noise source, 73 first noise observation point, 74 second noise observation point, Gcmn, Goff, Gon noise transfer function, 81 noise transfer function, 81a first noise transfer function, 81b second noise transfer function, 82-84 relay point, 101, 102 semiconductor device (noise source). 200 analysis target circuit, 201 input positive terminal, 202 input negative terminal, 203, 303 load, 204 capacitor, 205, 411, 412, 413 intermediate terminal, 220 CPU, 230 memory, 240 I/O circuit, 250 bus, 301 output positive terminal, 302 output negative terminal, 304 reactor, 401 first arm, 402 second arm, 403 third arm, 405 AC load, NS(i) simulated noise, NSoff(i) simulated turn-off noise, NSon(i) simulated turn-on noise, Prt1 to Prt4 port, RTNS simulated noise calculation result, SPNoff turn-off noise source spectrum, SPNon turn-on noise source spectrum, Tstr start time, Tend end time, Vdi diode voltage, Vtr transistor voltage, WGoff(i), WGon(i) weighting coefficient, X1-XJ, X(i) load current value, toff(i) turn-off time, ton(i) turn-on time, w(t) window function.

1. A noise analysis apparatus to calculate a sum spectrum of noise caused by switching that is at least one of turning on and turning off of a semiconductor device, comprising:
a first acquisition circuit to acquire information indicating a plurality of occurrence times at which switching of the semiconductor device occurs a plurality of times, respectively, for a noise analysis target period including the plurality of times of switching of the semiconductor device;
a phase transform circuit to generate a plurality of pieces of phase difference information respectively corresponding to the plurality of occurrence times acquired by the first acquisition circuit for subjecting a noise spectrum in the switching of the semiconductor device to a phase transform to reflect a time difference of the plurality of times of switching; and
a first addition circuit to calculate the sum spectrum, the sum spectrum being obtained by adding together a plurality of noise spectra obtained through a phase transform of the noise spectrum in the switching of the semiconductor device by the plurality of pieces of phase difference information, respectively.

2. The noise analysis apparatus according to claim 1, wherein the noise spectrum in the switching of the semiconductor device is a noise source spectrum obtained by Fourier transforming transient waveform data in the switching of the semiconductor device.

3. The noise analysis apparatus according to claim 1, further comprising:
a second acquisition circuit to acquire a noise transfer function for a propagation path between the semiconductor device and a noise observation point; and
a first multiplication circuit to calculate a multiplication value of a noise source spectrum obtained by Fourier transforming transient waveform data in the switching of the semiconductor device by the noise transfer function, wherein
the noise spectrum in the switching of the semiconductor device is the multiplication value.

4. The noise analysis apparatus according to claim 3, wherein the second acquisition circuit acquires a plurality of transfer functions respectively for a plurality of propagation paths providing division between the semiconductor device and the noise observation point,
the noise analysis apparatus further comprising a transfer function integration circuit to integrate the plurality of transfer functions acquired by the second acquisition circuit to output the noise transfer function.

5. The noise analysis apparatus according to claim 2, further comprising a third acquisition circuit to acquire the noise source spectrum, the noise source spectrum having undergone Fourier transform.

6. The noise analysis apparatus according to claim 2, further comprising:
a third acquisition circuit to acquire the transient waveform data; and
a Fourier transform circuit to generate the noise source spectrum by Fourier transforming the transient waveform data acquired by the third acquisition circuit.

7. (canceled)

8. The noise analysis apparatus according to claim 2, wherein the noise source spectrum and the plurality of occurrence times are set for each of the turning on and the turning off individually.

9. The noise analysis apparatus according to claim 2, further comprising:
a fifth acquisition circuit to acquire information of a load current passing through the semiconductor device for the noise analysis target period; and
a noise source spectrum correction circuit to correct the noise source spectrum in magnitude depending on the load current at each of the plurality of occurrence times.

10. The noise analysis apparatus according to claim 1, further comprising:
a fourth acquisition circuit to acquire information about a resolution bandwidth;
a window function setting circuit to set a window function in a shape reflecting the resolution bandwidth;
a weighting coefficient setting circuit to output values of the window function respectively for the plurality of occurrence times acquired by the first acquisition circuit as a plurality of weighting coefficients respectively for the plurality of occurrence times; and
a second multiplication circuit to multiply the plurality of noise spectra respectively by the plurality of weighting coefficients to calculate a plurality of multiplication values, wherein
the first addition circuit calculates a result of calculating the sum spectrum by adding together the plurality of multiplication values provided by the second multiplication unit.

11. The noise analysis apparatus according to claim 1, the semiconductor device being a plurality of semiconductor devices, the sum spectrum being calculated for noise caused by switching of the plurality of semiconductor devices, the noise analysis apparatus further comprising
a second addition circuit to sum a result of calculating the sum spectrum for each of the plurality of semiconductor devices to calculate a result of calculating the sum spectrum for the plurality of semiconductor devices.

12. The noise analysis apparatus according to claim 1, characterized in that the noise analysis target period is set to be a plurality of such noise analysis target periods, and a result of a statistical calculation of a plurality of sum spectra respectively for the plurality of set noise analysis target periods is output.

13. A noise analysis method for calculating a sum spectrum of noise caused by switching that is at least one of turning on and turning off of a semiconductor device, comprising:
acquiring information indicating a plurality of occurrence times at which switching of the semiconductor device occurs a plurality of times, respectively, for a noise analysis target period including the plurality of times of switching of the semiconductor device;
generating a plurality of pieces of phase difference information respectively corresponding to the plurality of occurrence times for subjecting a noise spectrum in the switching of the semiconductor device to a phase transform to reflect a time difference of the plurality of times of switching; and
calculating the sum spectrum, the sum spectrum being obtained by adding together a plurality of noise spectra obtained through a phase transform of the noise spectrum in the switching of the semiconductor device by the plurality of pieces of phase difference information, respectively.

14. The noise analysis method according to claim 13, wherein the noise spectrum in the switching of the semiconductor device is a noise source spectrum obtained by Fourier transforming transient waveform data in the switching of the semiconductor device.

15. The noise analysis method according to claim 13, further comprising:
acquiring a noise transfer function for a propagation path between the semiconductor device and a noise observation point; and
calculating a multiplication value of a noise source spectrum obtained by Fourier transforming transient waveform data in the switching of the semiconductor device by the noise transfer function, wherein
the noise spectrum in the switching of the semiconductor device is the multiplication value.

16. The noise analysis method according to claim 15, further comprising:
acquiring a plurality of transfer functions respectively for a plurality of propagation paths providing division between the semiconductor device and the noise observation point; and
calculating the multiplication value using the noise transfer function, the noise transfer function being an integration of the plurality of transfer functions acquired.

17. The noise analysis method according to claim 15, further comprising:
acquiring the noise source spectrum, the noise source spectrum having undergone Fourier transform; and
calculating the multiplication value using the acquired noise source spectrum.

18. The noise analysis method according to claim 15, further comprising:
acquiring the transient waveform data and Fourier transforming the acquired transient waveform data to generate the noise source spectrum; and
calculating the multiplication value using the generated noise source spectrum.

19. The noise analysis method according to claim 14, wherein the noise source spectrum and the plurality of occurrence times are set for each of the turning on and the turning off individually.

20. The noise analysis method according to claim 14, further comprising:
acquiring information of a load current passing through the semiconductor device for the noise analysis target period; and
correcting the noise source spectrum in magnitude depending on the load current at each of the plurality of occurrence times.

21. The noise analysis method according to claim 13, further comprising:
obtaining information about a resolution bandwidth;
setting a window function in a shape reflecting the resolution bandwidth;
setting values of the window function respectively for the plurality of acquired occurrence times as a plurality of weighting coefficients respectively for the plurality of occurrence times; and
multiplying the plurality of noise spectra respectively by the plurality of weighting coefficients to calculate a plurality of multiplication values; and
calculating a result of calculating the sum spectrum by adding together the plurality of multiplication values obtained through the multiplication by the plurality of weighting coefficients.

22. The noise analysis method according to claim 13, the semiconductor device being a plurality of semiconductor devices, the method further comprising, when calculating the sum spectrum for noise caused by switching of the plurality of semiconductor devices, summing a result of calculating the sum spectrum for each of the plurality of semiconductor devices to calculate a result of calculating the sum spectrum for the plurality of semiconductor devices.

23. The noise analysis method according to claim 13, the noise analysis target period being set to be a plurality of such noise analysis target periods, the method further comprising calculating a result of a statistical calculation of a plurality of sum spectra respectively for the plurality of set noise analysis target periods.

24. A program for causing a computer to perform the method according to claim 13.
